(19) United States
(12) Patent Application Publication
(10) Pub. No.: US 2025/0359432 A1
(43) Pub. Date: Nov. 20, 2025

(54) DISPLAY DEVICE

(71) Applicant: Samsung Display Co., LTD., Yongin-si (KR)

(72) Inventors: Kyung Bae KIM, Yongin-si (KR); Jin Seon KWAK, Yongin-si (KR); Dong Woo KIM, Yongin-si (KR); Yong Hee LEE, Yongin-si (KR)

(21) Appl. No.: 19/062,797

(22) Filed: Feb. 25, 2025

(30) Foreign Application Priority Data
May 20, 2024 (KR) 10-2024-0065045

(51) Int. Cl. H10K 59/121; H10K 59/127; H10K 59/131; H10K 59/80; H10K 102/00

(52) U.S. Cl. CPC H10K 59/1213; H10K 59/1275; H10K 59/131; H10K 59/80518; H10K 2102/351

(57) ABSTRACT

A display device includes a first single crystal semiconductor substrate, a connection wiring layer on the first single crystal semiconductor substrate, a second single crystal semiconductor substrate on the connection wiring layer, a display element layer on the second single crystal semiconductor substrate and including a first light emitting element in a first pixel and a second light emitting element in a second pixel, and a first step layer below the display element layer in the first pixel, wherein the first and second light emitting elements each include, an electrode assembly including a first electrode, a light emitting stack on the electrode assembly, and a second electrode on the light emitting stack, and wherein a distance between the electrode assembly and the second electrode in the first pixel is different from a distance between the electrode assembly and the second electrode in the second pixel.

### CROSS-REFERENCE TO RELATED APPLICATION

The present application claims priority to and the benefit of Korean Patent Application No. 10-2024-0065045, filed on May 20, 2024, in the Korean Intellectual Property Office, the entire content of which is incorporated herein by reference.

### BACKGROUND

### 1. Field

Embodiments of the present disclosure relate to a display device.

### 2. Description of the Related Art

As interest in extended reality (XR) increases (grows), new electronic devices and display devices capable of implementing extended reality (XR) are being developed. Extended reality includes virtual reality (VR), augmented reality (AR), and mixed reality (MR).

Various display devices for implementing extended reality are emerging. Non-limiting examples include head mounted displays (HMD) s and augmented reality (AR) glasses.

Additionally, research on small displays is progressing, driven by trends toward weight reduction and miniaturization. Non-limiting examples of small displays or electronic devices incorporating them include smartwatches, watch phones, head-up displays (HUDs) in automobiles, and the Internet of Things (IOT) devices.

A display device for implementing extended reality may be small in size and arranged (positioned) close to the user's eyes to magnify and display images or videos using a plurality of lenses. It is desirable for these small displays to provide clear images or videos while displaying (showing) a large amount of information on a small screen. Therefore, it is importable or desirable for the extended reality display devices (e.g., the small displays for implementing extended reality) to provide (offer) high-resolution images, such as those with a resolution of 3000 pixels per inch (PPI) or higher.

To achieve this, organic light emitting diodes on silicon (OLEDoS), which are high-resolution small organic light emitting display devices, may be used. OLEDOS display images by placing an organic light emitting diode (OLED) on a semiconductor wafer substrate that include a complementary metal oxide semiconductor (CMOS).

The information disclosed in this Background section is intended to enhance understanding of the background of the disclosure and may contain information that does not constitute prior art.

### SUMMARY

Aspects of one or more embodiments of the present disclosure are directed to a display device with improved light emission efficiency by adjusting a resonance distance of light emitted from light emitting elements.

Aspects of one or more embodiments of the present disclosure are directed to a display device including two different single crystal semiconductor substrates and having improved manufacturing yield, because having a single crystal semiconductor substrate arranged below the light emitting elements allows for a large number of single crystal semiconductor substrates to be manufactured per unit wafer substrate, thus simplifying the manufacturing process.

However, aspects of the present disclosure are not restricted to those set forth herein. Additional aspects will be set forth in part in the description which follows and, in part, will be apparent from the description, or may be learned by practice of the presented embodiments of the disclosure.

According to one or more embodiments of the present disclosure, a display device includes a first single crystal semiconductor substrate on which a first transistor is arranged (located), a connection wiring layer arranged on the first single crystal semiconductor substrate and including a connection wiring connected to the first transistor, a second single crystal semiconductor substrate arranged on the connection wiring layer and including a via connected to the connection wiring, a display element layer arranged on the second single crystal semiconductor substrate and including a first light emitting element arranged in a first pixel and a second light emitting element arranged in a second pixel, and a first step layer arranged below the display element layer in the first pixel, wherein the first light emitting element and the second light emitting element each include, an electrode assembly including a reflective electrode layer connected to the via and a first electrode arranged on the reflective electrode layer, a light emitting stack arranged on the electrode assembly, and a second electrode arranged on the light emitting stack, and wherein a distance between the electrode assembly and the second electrode in the first pixel is different from a distance between the electrode assembly and the second electrode in the second pixel.

In one or more embodiments, the distance between the electrode assembly and the second electrode in the first pixel may be less than the distance between the electrode assembly and the second electrode in the second pixel.

In one or more embodiments, a first portion of the electrode assembly of the first light emitting element may be in direct contact with the first step layer.

In one or more embodiments, a second portion of the electrode assembly of the first light emitting element may not be in contact with the first step layer, and the second portion may be in direct contact with the second single crystal semiconductor substrate.

In one or more embodiments, the display device may further include a pixel defining film arranged between the first light emitting element and the second light emitting element, wherein the second portion may overlap the pixel defining film.

In one or more embodiments, the second portion may be connected to the via.

In one or more embodiments, the first step layer may be covered by the electrode assembly of the first light emitting element.

In one or more embodiments, a shape of the electrode assembly of the first light emitting element may conform to shapes of upper and side surfaces of the first step layer.

In one or more embodiments, the electrode assembly of the second light emitting element may have a flat shape.

In one or more embodiments, an entirety of a lower surface of the electrode assembly of the second light emitting element may be in contact with the second single crystal semiconductor substrate.

In one or more embodiments, the display element layer may further include a third light emitting element arranged in a third pixel, the display device further includes a second step layer arranged below the display element layer in the third pixel, and a thickness of the second step layer may be different from a thickness of the first step layer.

In one or more embodiments, the distance between the electrode assembly and the second electrode in the first pixel, the distance between the electrode assembly and the second electrode in the second pixel, and a distance between the electrode assembly and the second electrode in the third pixel may be different from each other.

In one or more embodiments, a thickness of the electrode assembly in the first pixel may be smaller than a thickness of the electrode assembly in the third pixel, and the thickness of the electrode assembly in the third pixel may be smaller than a thickness of the electrode assembly in the second pixel.

In one or more embodiments, a thickness of the light emitting stack in the first pixel may be smaller than a thickness of the light emitting stack in the third pixel, and the thickness of the light emitting stack in the third pixel may be smaller than a thickness of the light emitting stack in the second pixel.

In one or more embodiments, a distance between a lower surface of the display element layer and a lower surface of the second electrode in the first pixel may be greater than a distance between a lower surface of the display element layer and a lower surface of the second electrode in the second pixel.

According to one or more embodiments of the present disclosure, a display device includes, a first single crystal semiconductor substrate on which a first transistor is arranged (located), a second single crystal semiconductor substrate arranged on the first single crystal semiconductor substrate and including a via connected to the first transistor, an electrode assembly including a reflective electrode layer connected to the via and a first electrode arranged on the reflective electrode layer, the electrode assembly including a first electrode assembly and a second electrode assembly spaced and/or apart (e.g., spaced apart or separated) from each other, a first step layer below the first electrode assembly, a light emitting stack arranged on the first electrode, and a second electrode arranged on the light emitting stack, wherein a distance between the first electrode assembly and the second electrode is different from a distance between the second electrode assembly and the second electrode.

In one or more embodiments, the distance between the first electrode assembly and the second electrode may be less than the distance between the second electrode assembly and the second electrode.

In one or more embodiments, the electrode assembly may include a third electrode assembly arranged to be spaced and/or apart (e.g., spaced apart or separated) from the first electrode assembly and the second electrode assembly, the display device may further include a second step layer arranged below the third electrode assembly, and a thickness of the second step layer may be different from a thickness of the first step layer.

In one or more embodiments, the distance between the first electrode assembly and the second electrode, the distance between the second electrode assembly and the second electrode, and a distance between the third electrode assembly and the second electrode may be different from each other.

In one or more embodiments, a distance between an upper surface of the second single crystal semiconductor substrate and a lower surface of the second electrode in an area where the first electrode assembly is arranged (located) may be greater than a distance between the upper surface of the second single crystal semiconductor substrate and the lower surface of the second electrode in an area where the second electrode assembly is arranged (located).

According to the display device according to one or more embodiments of the present disclosure, light emission efficiency may be improved by adjusting the resonance distance of light emitted from light emitting elements.

According to the display device according to one or more embodiments of the present disclosure, the display device may include two different single crystal semiconductor substrates, and have improved manufacturing yield because a process of manufacturing the single crystal semiconductor substrate arranged below the light emitting elements allows for a large number of single crystal semiconductor substrates to be manufactured per unit wafer substrate.

However, the effects of one or more embodiments are not restricted to the ones set forth herein. The above and other effects of one or more embodiments will become more apparent to one of daily skill in the art to which one or more embodiments pertain by referencing the claims.

### BRIEF DESCRIPTION OF THE DRAWINGS

The accompanying drawings are included to provide a further understanding of the present disclosure, and are incorporated in and constitutes a part of this disclosure. The drawings illustrate example embodiments of the present disclosure and, together with the description, serve to explain principles of the present disclosure. In the drawings:

FIG. 1 is an exploded perspective view of a display device according to one or more embodiments of the present disclosure;

FIG. 2 is a rear view illustrating an example of a driver illustrated in FIG. 1, according to one or more embodiments of the present disclosure;

FIG. 3 is a plan view illustrating an example of a display unit illustrated in FIG. 1, according to one or more embodiments of the present disclosure;

FIG. 4 is a block diagram illustrating the display device according to one or more embodiments of the present disclosure;

FIG. 5 is an equivalent circuit diagram of one pixel of the display device according to one or more embodiments of the present disclosure;

FIG. 6 is a schematic cross-sectional view of the display device according to one or more embodiments of the present disclosure;

FIG. 7 is a schematic view illustrating a rear surface of the display device according to one or more embodiments of the present disclosure;

FIG. 8 is a schematic cross-sectional view illustrating a display device according to one or more embodiments of the present disclosure;

FIG. 9 is a schematic cross-sectional view of a driver, a second single crystal semiconductor substrate of a display unit, and a connection wiring layer according to one or more embodiments of the present disclosure;

FIG. 10 is a plan view illustrating first electrodes, light emitting areas, and a pixel defining film of a plurality of sub-pixels arranged in a display area of the display unit according to one or more embodiments of the present disclosure;

FIG. 11 is a plan view illustrating first electrodes, light emitting areas, and a pixel defining film of a plurality of sub-pixels arranged in a display area of the display unit according to one or more embodiments of the present disclosure;

FIG. 12 is a schematic cross-section view illustrating a portion of a display layer according to one or more embodiments of the present disclosure;

FIG. 13 is a cross-section view illustrating a portion of the display layer according to one or more embodiments of the present disclosure;

FIG. 14 is an enlarged view of areas A, B, and C of FIG. 13, according to one or more embodiments of the present disclosure;

FIG. 15 is a schematic cross-sectional view of the display device according to one or more embodiments of the present disclosure;

FIG. 16 is a flowchart illustrating a method for manufacturing a display device according to one or more embodiments of the present disclosure;

FIG. 17 is a cross-sectional view illustrating step (e.g., act or task) S100 of FIG. 16, according to one or more embodiments of the present disclosure;

FIG. 18 is a cross-sectional view illustrating step (e.g., act or task) S200 of FIG. 16, according to one or more embodiments of the present disclosure;

FIG. 19 is a cross-sectional view illustrating step (e.g., act or task) S300 of FIG. 16, according to one or more embodiments of the present disclosure; and

FIGS. 20 and 21 are cross-sectional views illustrating step (e.g., act or task) S400 of FIG. 16, according to one or more embodiments of the present disclosure.

### DETAILED DESCRIPTION

The present disclosure may be modified in many alternate forms, and thus specific embodiments will be illustrated in the drawings and described in more detail. It should be understood, however, that this is not intended to limit the present disclosure to the particular forms disclosed, but rather, is intended to cover all modifications, equivalents, and alternatives falling within the spirit and scope of the present disclosure.

Hereinafter, example embodiments will be described in more detail with reference to the accompanying drawings. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described.

It will be understood that when an element, such as an area, layer, film, region or portion, is referred to as being “on,” “connected to,” or “coupled to” another element, it can be directly on, connected to, or coupled to the other element, or one or more intervening elements may be present. In contrast, when an element or layer is referred to as being “directly on,” “directly connected to”, “directly coupled to”, or “immediately adjacent to” another element or layer, there are no intervening elements or layers present. In addition, it will also be understood that when an element is referred to as being “between” two elements, it can be the only element between the two elements, or one or more intervening elements may also be present.

Unless otherwise noted, like reference numerals denote like elements throughout the attached drawings and the written description, and thus, duplicative descriptions thereof may not be provided. In the drawings, the relative sizes of elements, layers, and regions may be exaggerated for clarity.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

Spatially relative terms, such as “on,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the drawings. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

The terminology used herein is for the purpose of describing particular embodiments only and is not intended to be limiting of the present disclosure. As used herein, the singular forms “a,” “an” and “the” are intended to include the plural forms as well, unless the context clearly indicates otherwise. It will be further understood that the terms “comprises,” “comprising,” “includes,” “including,” “have,” and “having,” when used in this specification, specify the presence of the stated features, integers, steps, operations, elements, and/or components, but do not preclude the presence or addition of one or more other features, integers, steps, operations, elements, components, and/or groups thereof.

As used herein, the term “and/or” includes any and all combinations of one or more of the associated listed items. Unless otherwise apparent from the disclosure, expressions such as “at least one of,” “a plurality of,” “one of,” and other prepositional phrases, when preceding a list of elements, should be understood as including the disjunctive if written as a conjunctive list and vice versa. For example, the expressions “at least one of a, b, or c,” “at least one of a, b, and/or c,” “one selected from the group consisting of a, b, and c,” “at least one selected from among a, b, and c,” “at least one from among a, b, and c,” “one from among a, b, and c”, “at least one of a to c” indicates only a, only b, only c, both a and b, both a and c, both b and c, all of a, b, and c, or variations thereof.

As used herein, the terms “use,” “using,” and “used” may be considered synonymous with the terms “utilize,” “utilizing,” and “utilized,” respectively.

Hereinafter, embodiments of the present disclosure will be described in more detail with reference to the accompanying drawings.

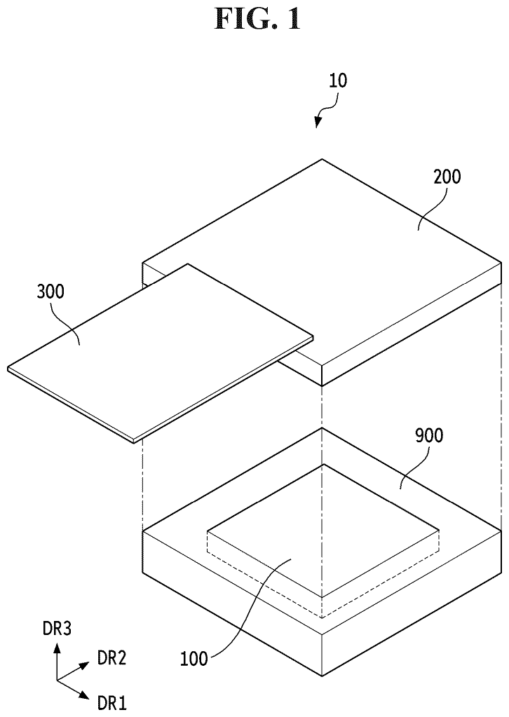

FIG. 1 is an exploded perspective view of the display device according to one or more embodiments of the present disclosure.

Referring to FIG. 1, a display device 10 according to one or more embodiments is a device that displays a moving image and/or a still image. The display device 10 according to one or more embodiments may be applied to electronic devices including portable electronic devices such as mobile phones, smart phones, tablet personal computers (PC), mobile communication terminals, electronic notebooks, electronic books, portable multimedia players (PMP), navigations, and ultra mobiles PC (UMPC). For example, the display device 10 may be applied to a display unit of a television, a laptop computer, a monitor, a billboard, or the Internet of Things (IOT) device. Alternatively, in one or more embodiments, the display device 10 may be applied to a smart watch, a watch phone, and/or a head mounted display device (HMD) for implementing virtual reality and/or augmented reality.

The display device 10 according to one or more embodiments may include a driver 100, a display unit 200, and a circuit board 300. The display device 10 may further include a protective layer 900 arranged around the driver 100.

The driver 100 may have a planar shape similar to a quadrangle. For example, the driver 100 may have a planar shape similar to a rectangle having a first dimension (e.g., length or width) in a first direction DR1 and a second dimension (e.g., length or width) in a second direction DR2 intersecting the first direction DR1 (e.g., the driver 100 may have a planar shape in a plane defined by the first direction DR1 and the second direction DR2 and/or in a plan view). The first dimension (e.g., length or width) of the driver 100 in the first direction DR1 and the second dimension (e.g., length or width) in the second direction DR2 may have different lengths. In the driver 100, a corner where the first dimension in the first direction DR1 and the second dimension in the second direction DR2 meet may be rounded to have a set or predetermined curvature or may be formed at a right angle. The planar shape of the driver 100 is not limited to the quadrangle, and may be formed similarly to other polygons, circles, or ovals.

In the illustrated drawings, the first direction DR1 and the second direction DR2 are horizontal directions and intersect each other. For example, the first direction DR1 and the second direction DR2 may be orthogonal to each other. In addition, a third direction DR3 may be a vertical direction intersecting the first direction DR1 and the second direction DR2. For example, the third direction DR3 may be orthogonal to the first direction DR1 and the second direction DR2. A plan view refers to a view from above, looking down along the third direction DR3. Unless otherwise defined, in the present specification, directions indicated by arrows in the first to third directions DR1, DR2, and DR3 may be referred to as one side, and the opposite directions thereof may be referred to as the other side. In addition, in the present specification, “on”, “upper side”, “upper portion”, “top”, and “upper surface” refer to a direction in which an arrow in the drawing is directed in a third direction DR3 based on the drawing, and “below”, “lower side”, “lower portion”, “bottom”, and “lower surface” refer to a direction opposite to the direction in which the arrow in the third direction DR3 is directed based on the drawings.

The display unit 200 may be arranged on the driver 100. In the display device 10, the driver 100 and the display unit 200 may be bonded to each other. Unlike the driver 100, the display unit 200 may have a shape similar to a square. For example, the display unit 200 may have a planar shape similar to a square having a first dimension (e.g., length or width) in the first direction DR1 and a second dimension (e.g., length or width) in the second direction DR2 intersecting the first direction DR1 (e.g., the display unit 200 may have a planar shape in a plane defined by the first direction DR1 and the second direction DR2 and/or in a plan view). The planar shape of the display unit 200 is not limited to the quadrangle, and may be formed similarly to other polygons, circles, or ovals. A planar shape of the display device 10 may follow the planar shape of the display unit 200, but the present disclosure is not limited thereto.

According to one or more embodiments, in the display device 10, a planar area of the display unit 200 may be greater than a planar area of the driver 100. The display device 10 includes the driver 100 and the display unit 200 that include different substrates, and the driver 100 and the display unit 200 may have different areas. An element (e.g., components) formed in the driver 100 and an element (e.g., components) formed in the display unit 200 may be different from each other, and the elements may be individually formed on different substrates. The display device 10 may be manufactured by forming a plurality of elements with different sizes, line widths, and manufacturing processes on different substrates and then bonding the substrates, and has an advantage of improving performance and manufacturing yield of a product.

The circuit board 300 may be electrically connected to a plurality of pads of a pad area of the display unit 200 by using a conductive adhesive member such as an anisotropic conductive film. The circuit board 300 may be a flexible printed circuit board or flexible film made of a flexible material. It is illustrated in FIG. 1 that the circuit board 300 is unfolded, but the circuit board 300 may be bent. In this case, one end of the circuit board 300 may be arranged on a lower surface of the driver 100. The other end of the circuit board 300 may be connected to the plurality of pads in the pad area of the display unit 200 using a conductive adhesive member. In one or more embodiments, the circuit board 300 may also be attached to the lower surface of the driver 100.

The protective layer 900 may be around (e.g., surround) the driver 100 and may be arranged on a lower surface of the display unit 200. The protective layer 900 may reduce a level difference caused by a difference in area between the driver 100 and the display unit 200, and may also protect the driver 100 and the display unit 200.

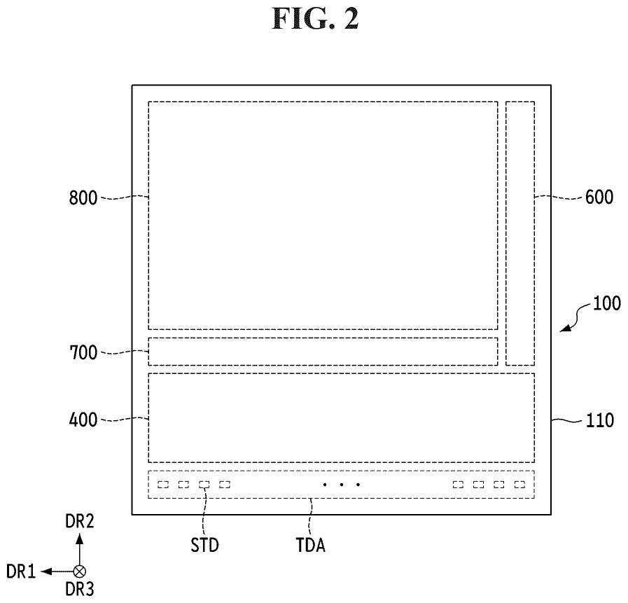

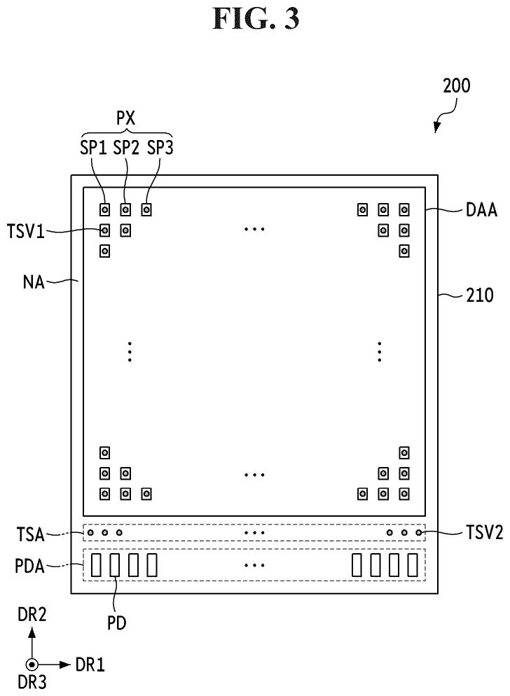

FIG. 2 is a rear view illustrating an example of the driver 100 illustrated in FIG. 1, according to one or more embodiments of the present disclosure. FIG. 3 is a plan view illustrating an example of the display unit 200 illustrated in FIG. 1, according to one or more embodiments of the present disclosure. FIG. 2 illustrates the driver 100 as viewed from the rear of the display device 10, and FIG. 3 illustrates the display unit 200 as viewed from the front of the display device 10.

Referring to FIGS. 2 and 3, the driver 100 of the display device 10 may include driving circuit elements of the display device 10. The driver 100 may include a first single crystal semiconductor substrate 110 and a driving circuit unit 400, a gate driver 600, a data driver 700, and a pixel circuit unit 800 formed on the first single crystal semiconductor substrate 110.

The first single crystal semiconductor substrate 110 may be a silicon substrate, a germanium substrate, or a silicon-germanium substrate. A plurality of first transistors may be formed on the first single crystal semiconductor substrate 110, and the plurality of first transistors may be electrically connected to each other to form the driving circuit unit 400, the gate driver 600, the data driver 700, and the pixel circuit unit 800. The first transistors may be formed through a semiconductor process. For example, the plurality of transistors may be formed as complementary metal oxide semiconductor (CMOS) transistors.

It is illustrated in the drawings that the pixel circuit unit 800 is arranged on an upper side of the driver 100, the data driver 700, the driving circuit unit 400, and a signal terminal area TDA are arranged on a lower side thereof, and the gate driver 600 is arranged on a right side, which is the other side of the pixel circuit unit 800 in the first direction DR1. However, the present disclosure is not limited thereto. In the driver 100, the positions of the driving circuit unit 400, the gate driver 600, the data driver 700, and the pixel circuit unit 800 may be modified in one or more suitable ways depending on the design structure of the plurality of circuit elements formed on the first single crystal semiconductor substrate 110.

A plurality of signal terminals STD arranged in the first direction DR1 may be arranged in the signal terminal area TDA. The plurality of signal terminals STD may be electrically connected to the display unit 200 and may be electrically connected to the circuit board 300 through the display unit 200. The signal terminals STD may be to transmit electrical signals applied from the circuit board 300 to the driving circuit unit 400, the gate driver 600, the data driver 700, and/or the pixel circuit unit 800.

As shown, for example, in FIG. 3, the display unit 200 may include a second single crystal semiconductor substrate 210 and a plurality of pixels PX formed on the second single crystal semiconductor substrate 210. The display unit 200 may include a display area DAA where the plurality of pixels PX are arranged and a non-display area NA around the display area DAA. A through hole area TSA and a pad area PDA may be arranged in the non-display area NA.

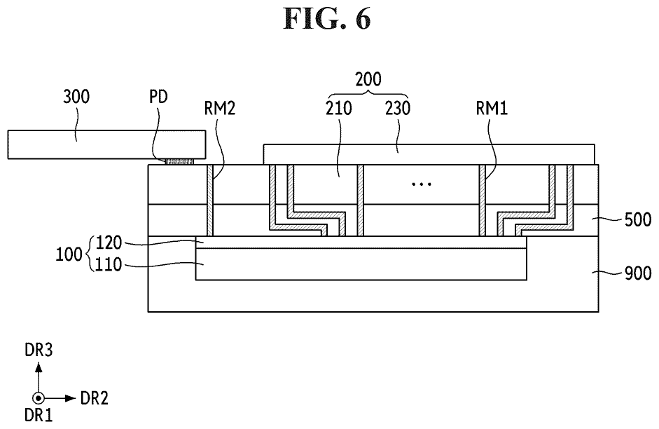

The second single crystal semiconductor substrate 210 may be a silicon substrate, a germanium substrate, or a silicon-germanium substrate. Unlike the first single crystal semiconductor substrate 110, the transistors may not be formed in the second single crystal semiconductor substrate 210. A display layer 230 (see, e.g., FIG. 6) in which a plurality of light emitting elements are arranged may be arranged on the second single crystal semiconductor substrate 210, and the plurality of light emitting elements included in the display layer 230 (see, e.g., FIG. 6) may be electrically connected to the pixel circuit unit 800 formed on the first single crystal semiconductor substrate 110.

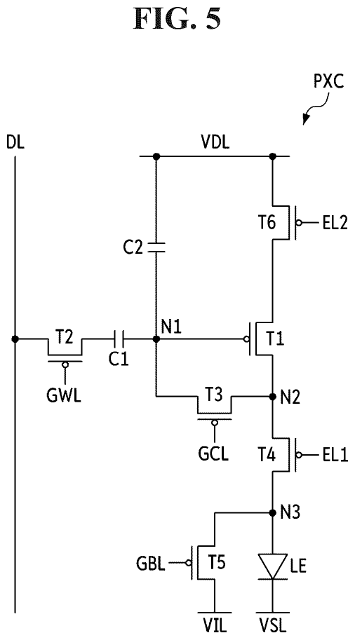

A plurality of pixels PX including light emitting elements may be arranged in the display area DAA. Each of the plurality of pixels PX may include three sub-pixels, for example, a first sub-pixel SP1, a second sub-pixel SP2, and a third sub-pixel SP3. The three sub-pixels SP1, SP2, and SP3 may form one pixel PX and may display a color of light. However, the present disclosure is not limited thereto, and one pixel PX may include three or more sub-pixels. The plurality of sub-pixels SP may be arranged in a matrix form in the first direction DR1 and the second direction DR2. Each of the plurality of sub-pixels SP1, SP2, and SP3 may be electrically connected to a pixel circuit PXC (see, e.g., FIG. 5) of the pixel circuit unit 800 formed on the first single crystal semiconductor substrate 110. Each of the sub-pixels SP1, SP2, and SP3 may include light emitting elements, and the light emitting elements may be to emit light according to an electrical signal applied from the pixel circuit PXC (see, e.g., FIG. 5) arranged in the display area DAA.

Some of the sub-pixels SP1, SP2, and SP3 arranged in the display area DAA of the display unit 200 may overlap the driver 100 in a thickness direction, and others may not overlap the driver 100. The driver 100 may have a smaller area than the display unit 200 and may be arranged adjacent to one side of the display unit 200. Accordingly, only some of the plurality of sub-pixels SP1, SP2, and SP3 may overlap the driver 100 in the thickness direction.

According to one or more embodiments, the display unit 200 of the display device 10 may include a plurality of first through holes TSV1 that overlap the display area DAA. The first through holes TSV1 may be formed to penetrate through the second single crystal semiconductor substrate 210 of the display unit 200. The first through-holes TSV1 may form a connection path between the pixel circuit unit 800 of the driver 100 and each of the sub-pixels SP1, SP2, and SP3 of the display unit 200. The plurality of first through holes TSV1 may be formed to each correspond to the sub-pixels SP1, SP2, and SP3 of the display unit 200. In one or more embodiments, the number of first through holes TSV1 may be the same as the number of sub-pixels SP1, SP2, and SP3, and the first through holes TSV1 may be formed to overlap the sub-pixels SP1, SP2, and SP3, respectively. However, the present disclosure is not limited thereto. The plurality of first through holes TSV1 may each correspond to the sub-pixels SP1, SP2, and SP3, but may not necessarily be formed to overlap the sub-pixels SP1, SP2, and SP3. As will be described in more detail later, the plurality of sub-pixels SP1, SP2, and SP3 may be electrically connected to the pixel circuit of the pixel circuit unit 800 through a connection wiring arranged in the first through hole TSV1.

The non-display area NA may be arranged to be around (e.g., surround) the display area DAA. The non-display area NA may be an area where no light is emitted because the pixels PX are not arranged in the non-display area NA. A through hole area TSA and a pad area PDA may be arranged in the non-display area NA.

The pad area PDA may be arranged on a lower side, which is one side of the display area DAA in the second direction DR2. A plurality of pads PD arranged in the first direction DR1 may be arranged in the pad area PDA. The circuit board 300 may be attached onto the plurality of pads PD. The pads PD may be electrically connected to the circuit board 300 and may be to transmit the electrical signals applied from the circuit board 300 to the driver 100.

The through hole area TSA may be arranged between the pad area PDA and the display area DAA. A plurality of second through holes TSV2 may be formed in the through hole area TSA. The second through-holes TSV2 may be connection paths of signal connection wirings that electrically connect the signal terminals STD of the driver 100 and the circuit board 300. The plurality of second through holes TSV2 may be formed to correspond to the signal terminals STD of the driver 100, respectively. In one or more embodiments, the number of second through holes TSV2 may be the same as the number of signal terminals STD, and each of the second through holes TSV2 may be formed to overlap the signal terminal STD. However, the present disclosure is not limited thereto. The circuit board 300 may be electrically connected to the signal terminals STD of the driver 100 through the plurality of pads PD and the signal connection wirings arranged in the second through holes TSV2.

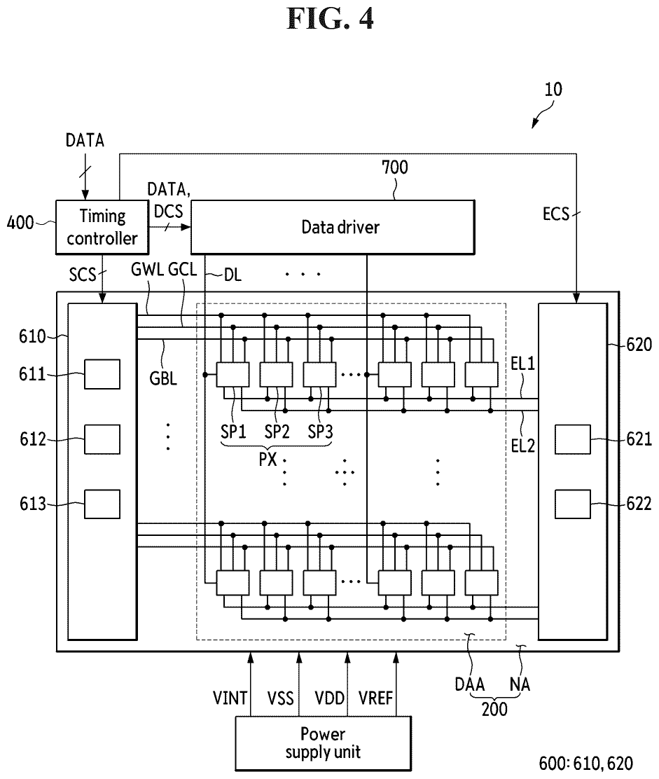

FIG. 4 is a block diagram illustrating the display device according to one or more embodiments of the present disclosure.

Referring to FIG. 4, the driving circuit unit 400 may include a timing control circuit. In one or more embodiments, the driving circuit unit 400 may further include one or more suitable circuits involved in driving the display device 10, such as a gamma circuit and/or a logic circuit. The driving circuit unit 400 may include driving circuit transistors formed on the first single crystal semiconductor substrate 110.

The driving circuit unit 400 (also referred to as a timing controller) may receive digital video data and timing signals from the outside. The timing control circuit may generate a scan timing control signal SCS, an emission timing control signal ECS, and a data timing control signal DCS for controlling the display unit 200 according to the timing signals. The timing control circuit may output the scan timing control signal SCS to a scan driver 610 of the gate driver 600 and output the emission timing control signal ECS to a light emitting driver 620 of the gate driver 600. The timing control circuit may output the digital video data and the data timing control signal DCS to the data driver 700.

The power supply unit (see, “Power supply unit,” of FIG. 4) may generate a plurality of panel driving voltages according to a power voltage from the outside. For example, the power supply unit may generate a first driving voltage VSS, a second driving voltage VDD, a reference voltage VREF, and an initialization voltage VINT and supply the voltages to the plurality of pixels PX.

The scan timing control signal SCS, the emission timing control signal ECS, the digital video data DATA, and the data timing control signal DCS of the driving circuit unit 400 (e.g., timing controller) may be supplied to the plurality of pixels PX. The first driving voltage VSS, the second driving voltage VDD, and the initialization voltage VINT of the power supply unit may also be supplied to the plurality of pixels PX.

The gate driver 600 may include a scan driver 610 and a light emitting driver 620. The scan driver 610 may include a plurality of scan transistors formed on the first single crystal semiconductor substrate 110, and the light emitting driver 620 may include a plurality of light emitting transistors formed on the first single crystal semiconductor substrate 110. The plurality of scan transistors and the plurality of light emitting transistors may be formed through a semiconductor process. For example, the plurality of scan transistors and the plurality of light emitting transistors may be formed of CMOS transistors.

The scan driver 610 may include a first scan signal output unit 611, a second scan signal output unit 612, and a third scan signal output unit 613. Each of the first scan signal output unit 611, the second scan signal output unit 612, and the third scan signal output unit 613 may receive a scan timing control signal SCS from the driving circuit unit 400. The first scan signal output unit 611 may generate write scan signals according to the scan timing control signal SCS of the driving circuit unit 400 and sequentially output the write scan signals to first scan lines GWL. The second scan signal output unit 612 may generate control scan signals according to the scan timing control signal SCS and sequentially output the control scan signals to second scan lines GCL. The third scan signal output unit 613 may generate bias scan signals according to the scan timing control signal SCS and sequentially output the bias scan signals to third scan lines GBL.

The light emitting driver 620 may include a first light emitting signal output unit 621 and a second light emitting signal output unit 622. Each of the first light emitting signal output unit 621 and the second light emitting signal output unit 622 may receive the emission timing control signal ECS from the driving circuit unit 400. The light emitting driver 620 may generate emission control signals according to the emission timing control signal ECS and sequentially output the emission control signals to first and second emission control lines EL1 and EL2.

The data driver 700 may receive the digital video data DATA and the data timing control signal DCS from the driving circuit unit 400. The data driver 700 converts the digital video data DATA into analog data voltages according to the data timing control signal DCS and outputs the converted analog data voltages to the data lines DL. In this case, the sub-pixels SP1, SP2, and SP3 may be selected by the write scan signals of the scan driver 610, and the data voltages may be supplied to the selected sub-pixels SP1, SP2, and SP3.

The pixel circuit unit 800 includes a plurality of pixel transistors formed on the first single crystal semiconductor substrate 110. The plurality of pixel transistors may be formed through a semiconductor process. For example, the plurality of pixel transistors may be formed of CMOS transistors.

A plurality of data lines DL, a plurality of scan lines GWL, GCL, and GBL, and a plurality of emission control lines EL1 and EL2 may be arranged in the pixel circuit unit 800. The plurality of scan lines GWL, GCL, and GBL and the plurality of emission control lines EL1 and EL2 may extend in the first direction DR1 and may be arranged to be spaced and/or apart (e.g., spaced apart or separated) from each other in the second direction DR2. The plurality of data lines DL may extend in the second direction DR2 and may be arranged to be spaced and/or apart (e.g., spaced apart or separated) from each other in the first direction DR1. The pixel circuit unit 800 may be electrically connected to the pixels PX of the display unit 200 and may be to transmit electrical signals necessary for the light emitting device to emit light. The plurality of data lines DL, the plurality of scan lines GWL, GCL, and GBL, and the plurality of emission control lines EL1 and EL2 may be connected to the plurality of pixels PX of the display unit 200.

FIG. 5 is an equivalent circuit diagram of one pixel according to one or more embodiments of the present disclosure.

Referring to FIG. 5, a pixel circuit PXC of the sub-pixel may be connected to the first scan line GWL, the second scan line GCL, the third scan line GBL, the first emission control line EL1, the second emission control line EL2, and the data line DL. In one or more embodiments, the pixel circuit PXC may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied. For example, the first driving voltage line VSL may be a low potential voltage line, the second driving voltage line VDL may be a high potential voltage line, and the third driving voltage line VIL may be an initialization voltage line. In such embodiments, the first driving voltage VSS may be a voltage lower than the third driving voltage VINT. The second driving voltage VDD may be a voltage higher than the third driving voltage VINT.

The pixel circuit PXC includes a plurality of transistors T1 to T6, a light emitting element LE, a first capacitor C1, and a second capacitor C2.

The light emitting element LE emits light according to a driving current Ids flowing through a channel of a first transistor T1. An amount of light emitted from the light emitting element LE may be proportional to the driving current Ids. The light emitting element LE may be arranged between a fourth transistor T4 and the first driving voltage line VSL. A first electrode of the light emitting element LE may be connected to a drain electrode of the fourth transistor T4, and a second electrode thereof may be connected to the first driving voltage line VSL. The first electrode of the light emitting element LE may be an anode electrode, and the second electrode of the light emitting element LE may be a cathode electrode. The light emitting element LE may be an organic light emitting diode including a first electrode, a second electrode, and an organic light emitting layer arranged between the first electrode and the second electrode, but the present disclosure is not limited thereto. For example, the light emitting element LE may be an inorganic light emitting element including a first electrode, a second electrode, and an inorganic semiconductor arranged between the first electrode and the second electrode. In such embodiments, the light emitting element LE may be a micro light emitting diode.

The first transistor T1 may be a driving transistor that controls a source-drain current (Ids, hereinafter, referred to as “driving current”) flowing between a source electrode and a drain electrode according to a voltage applied to a gate electrode. The first transistor T1 includes a gate electrode connected to a first node N1, a source electrode connected to a drain electrode of a sixth transistor T6, and a drain electrode connected to a second node N2.

The second transistor T2 may be arranged between one electrode of the first capacitor C1 and the data line DL. The second transistor T2 is turned on by the write scan signal of the first scan line GWL and connects one electrode of the first capacitor C1 to the data line DL. Accordingly, the data voltage of the data line DL may be applied to one electrode of the first capacitor C1. The second transistor T2 includes a gate electrode connected to the first scan line GWL, a source electrode connected to the data line DL, and a drain electrode connected to one electrode of the first capacitor C1.

A third transistor T3 may be arranged between the first node N1 and the second node N2. The third transistor T3 is turned on by the write control signal of the second scan line GCL and connects the first node N1 to the second node N2. Accordingly, because the gate electrode and the source electrode of the first transistor T1 are connected, the first transistor T1 may operate like a diode. The third transistor T3 includes a gate electrode connected to the second scan line GCL, a source electrode connected to the second node N2, and a drain electrode connected to the first node N1.

A fourth transistor T4 may be arranged between the second node N2 and a third node N3. The fourth transistor T4 is turned on by the first emission control signal of the first emission control line EL1 and connects the second node N2 to the third node N3. Accordingly, the driving current of the first transistor T1 may be supplied to the light emitting element LE. The fourth transistor T4 includes a gate electrode connected to the first emission control line EL1, a source electrode connected to the second node N2, and a drain electrode connected to the third node N3.

A fifth transistor T5 may be arranged between the third node N3 and the third driving voltage line VIL. The fifth transistor T5 is turned on by the bias scan signal of the third scan line GBL and connects the third node N3 to the third driving voltage line VIL. Accordingly, the third driving voltage VINT of the third driving voltage line VIL may be applied to the first electrode of the light emitting element LE. The fifth transistor T5 includes a gate electrode connected to the third scan line GBL, a source electrode connected to the third node N3, and a drain electrode connected to the third driving voltage line VIL.

A sixth transistor T6 may be arranged between the source electrode of the first transistor T1 and the second driving voltage line VDL. The sixth transistor T6 is turned on by the second emission control signal of the second emission control line EL2 and connects the source electrode of the first transistor T1 to the second driving voltage line VDL. Accordingly, the second driving voltage VDD of the second driving voltage line VDL may be applied to the source electrode of the first transistor T1. The sixth transistor T6 includes a gate electrode connected to the second emission control line EL2, a source electrode connected to the second driving voltage line VDL, and a drain electrode connected to the source electrode of the first transistor T1.

The first capacitor C1 is formed between the first node N1 and the drain electrode of the second transistor T2. The first capacitor C1 includes one electrode connected to the drain electrode of the second transistor T2 and the other electrode connected to the first node N1.

The second capacitor C2 is formed between the gate electrode of the first transistor T1 and the second driving voltage line VDL. The second capacitor C2 includes one electrode connected to the gate electrode of the first transistor T1 and the other electrode connected to the second driving voltage line VDL.

The first node N1 is a contact point of the gate electrode of the first transistor T1, the drain electrode of the third transistor T3, the other electrode of the first capacitor C1, and one electrode of the second capacitor C2. The second node N2 is a contact point of the drain electrode of the first transistor T1, the source electrode of the third transistor T3, and the source electrode of the fourth transistor T4. The third node N3 is a contact point of the drain electrode of the fourth transistor T4, the source electrode of the fifth transistor T5, and the first electrode of the light emitting element LE.

Each of the first to sixth transistors T1 to T6 may be a metal-oxide-semiconductor field effect transistor (MOSFET). For example, each of the first to sixth transistors T1 to T6 may be a P-type (kind) MOSFET, but the present disclosure is not limited thereto. Each of the first to sixth transistors T1 to T6 may be an N-type (kind) MOSFET. In one or more embodiments, each of some of the first to sixth transistors T1 to T6 may be a P-type (kind) MOSFET, and each of the remaining transistors may be an N-type (kind) MOSFET.

It is illustrated in FIG. 5 that the pixel circuit PXC includes the six transistors T1 to T6 and the two capacitors C1 and C2, but it should be noted that the equivalent circuit diagram of the pixel circuit PXC is not limited to that illustrated in FIG. 5. For example, the number of transistors and capacitors of the pixel circuit PXC is not limited to that illustrated in FIG. 5.

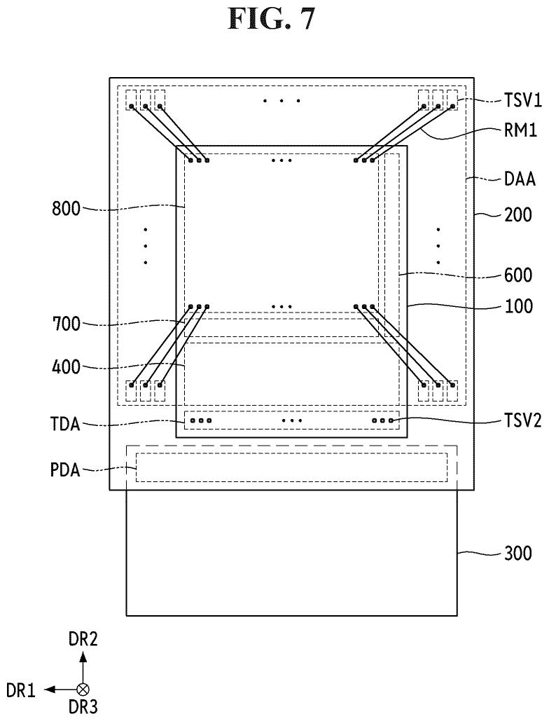

FIG. 6 is a schematic cross-sectional view of the display device according to one or more embodiments of the present disclosure. FIG. 7 is a schematic view illustrating a rear (bottom) surface of the display device according to one or more embodiments of the present disclosure. FIG. 6 illustrates a schematic connection relationship of routing wirings RM1 and RM2 that electrically connect the display unit 200 and the driver 100, and FIG. 7 illustrates an arrangement of the through holes TSV1 and TSV2 and the routing wirings RM1 and RM2 as viewed from a rear (bottom) surface of the display device 10.

Referring to FIGS. 6 and 7 in conjunction with FIG. 4, the display device 10 according to one or more embodiments may include a driver 100 including a first single crystal semiconductor substrate 110 and a driving circuit layer 120 arranged on the first single crystal semiconductor substrate 110, and a display unit 200 including a second single crystal semiconductor substrate 210 and a display layer 230 arranged on the second single crystal semiconductor substrate 210. The display device 10 may include two different single crystal semiconductor substrates 110 and 210 that overlap in the third direction DR3, which is the thickness direction of the display device 10.

The driver 100 may include circuit elements necessary for the light emitting elements included in the display layer 230 of the display unit 200 to emit light. As described above, the driving circuit layer 120 of the driver 100 may include the driving circuit unit 400, the gate driver 600, the data driver 700, and the pixel circuit unit 800, and the circuit elements that constitute the driving circuit unit 400, the gate driver 600, the data driver 700, and the pixel circuit unit 800, such as transistors and capacitors, may be formed of CMOS on the first single crystal semiconductor substrate 110. For example, the circuit elements that constitute the driving circuit unit 400, the gate driver 600, the data driver 700, and the pixel circuit unit 800, such as CMOS transistors and capacitors, may be formed on the first single crystal semiconductor substrate 110.

The display unit 200 may include a plurality of light emitting elements that emit light to display an image of the display device 10. The light emitting elements may be electrically connected to the circuit elements formed in the driver 100 and emit light.

According to one or more embodiments, the display device 10 may have a planar area of the driver 100 or the first single crystal semiconductor substrate 110 that is smaller than the planar area of the display unit 200 or the second single crystal semiconductor substrate 210. The plurality of transistors formed in the driver 100 may be formed through a semiconductor micro process and may have very small sizes or line widths. The driver 100 has an advantage that a large number of circuit elements may be arranged with high integration, and power consumption is reduced due to miniaturization in sizes of the elements.

In one or more embodiments, because the driver 100 includes only the circuit elements formed of the CMOS on the first single crystal semiconductor substrate 110 and does not include the light emitting elements, it may be sufficient to secure just enough space to dispose the elements formed through the micro process. It is sufficient for the first single crystal semiconductor substrate 110 to have a smaller area than the second single crystal semiconductor substrate 210, and because a large number of drivers 100 may be manufactured on one wafer substrate on which a process of forming the driving circuit layer 120 is performed, manufacturing yield may be improved. For example, if (e.g., when) a high-cost semiconductor process is performed on the driver 100, cost reduction may be achieved by improving the manufacturing yield of the driver 100. In one or more embodiments, in the display unit 200, a large number of light emitting elements may be formed on the second single crystal semiconductor substrate 210 with a relatively large area, thereby making it possible to implement a high-resolution display device.

The display device 10 may include a connection wiring layer 500 arranged between the second single crystal semiconductor substrate 210 of the display unit 200 and the driving circuit layer 120 of the driver 100. The connection wiring layer 500 may be arranged on a lower surface of the second single crystal semiconductor substrate 210. A portion of the plurality of routing wirings RM1 and RM2 may be arranged in the connection wiring layer 500, and the routing wirings RM1 and RM2 may connect the display layer 230 of the display unit 200 and the circuit board 300 with the driver 100. The driving circuit layer 120 of the driver 100 may be electrically connected to the display unit 200 and the circuit board 300 through the routing wirings RM1 and RM2 and transmit electrical signals for light emission.

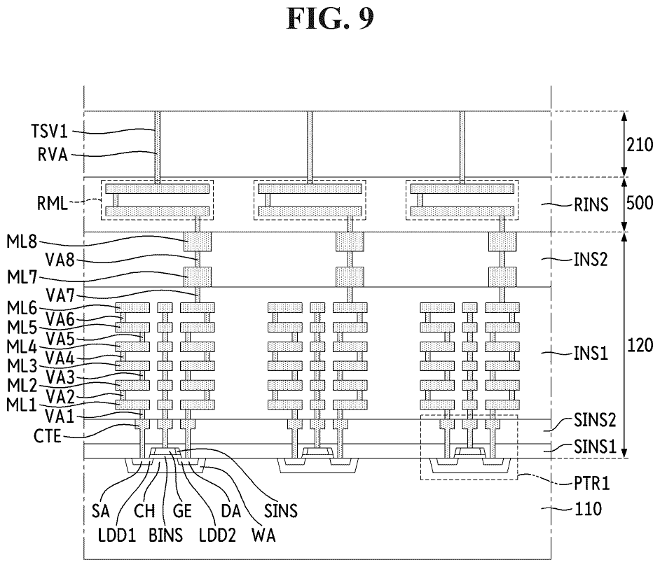

The first routing wiring RM1 may be connected to the sub-pixels SP1, SP2, and SP3 arranged on the display layer 230 of the display unit 200 and the pixel circuit unit 800 of the driver 100. In one or more embodiments, the display device 10 may include a plurality of first through holes TSV1 arranged to correspond to the sub-pixels SP1, SP2, and SP3 of the display unit 200, and the first routing wiring RM1 may each connect the first through holes TSV1 to the pixel circuit unit 800. While the first through holes TSV1 are arranged throughout the display unit 200 with a large area, the pixel circuit unit 800 may have a relatively small area. The first routing wiring RM1 may include conductive vias RVA (see, e.g., FIG. 9) arranged throughout the display unit 200 with the large area and a connection wiring RML (see, e.g., FIG. 9) connecting the conductive vias to the pixel circuit unit 800 with the small area. A gap between the first routing wiring RM1 and another first routing wiring RM1 adjacent thereto in plan view may be narrower in a portion overlapping the driver 100 than in the display area DAA.

In one or more embodiments, some of the plurality of first through holes TSV1 may overlap the driver 100 in the thickness direction, and other portions may not overlap the driver 100 in the thickness direction. In the first routing wiring RM1 arranged in the first through holes TSV1 that do not overlap the driver 100, some of the connection wirings RML (see, e.g., FIG. 9) may not overlap the driver 100. However, the arrangement of the first through holes TSV1 may vary depending on a position of a layer where the connection wirings RML (see, e.g., FIG. 9) of the first routing wirings RM1 are arranged.

According to one or more embodiments, the number of first through holes TSV1 may be the same as the number of sub-pixels SP1, SP2, and SP3 arranged in the display area DAA. For example, the plurality of sub-pixels SP1, SP2, and SP3 may be arranged in the first direction DR1 and the second direction DR2 in the display area DAA, and the first through holes TSV1 may also be arranged in the first direction DR1 and the second direction DR2 and may correspond to each sub-pixel SP1, SP2, and SP3 in a one-to-one manner. The first through holes TSV1 may be formed to overlap each sub-pixel SP1, SP2, and SP3. The number of first routing wirings RM1 may also be the same as the number of sub-pixels SP1, SP2, and SP3.

The plurality of second through holes TSV2 may be arranged in the through hole area TSA of the display unit 200 (see, e.g., FIG. 7) and may be formed to overlap the signal terminal area TDA of the driver 100. A second routing wiring RM2 connected to the signal terminal STD of the driver 100 may be arranged in the second through holes TSV2. Unlike the first through hole TSV1, the second through hole TSV2 may be formed to overlap each signal terminal STD of the driver 100 (see, e.g., FIG. 1). Accordingly, the second routing wiring RM2 may also be arranged to correspond to and overlap the signal terminals STD. The second routing wiring RM2 may be a wiring that transmits a signal applied from the circuit board 300 to the driver 100.

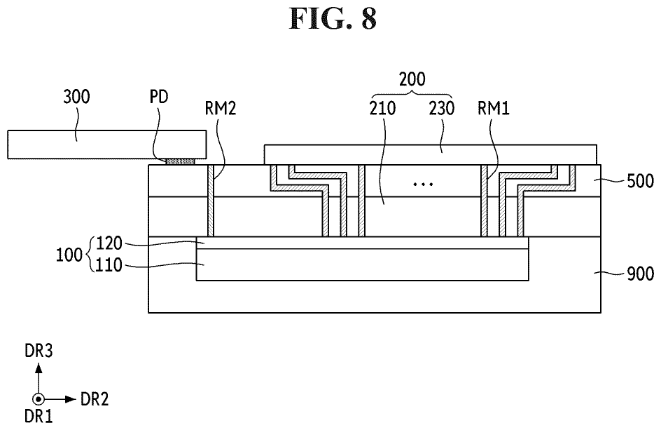

FIG. 8 is a schematic cross-sectional view illustrating a display device according to one or more embodiments of the present disclosure.

Referring to FIG. 8, in a display device 10 according to one or more embodiments, the connection wiring layer 500 may be arranged between the display layer 230 and the second single crystal semiconductor substrate 210. Such embodiments are different from the one or more embodiments of FIGS. 6 and 7, in that as the connection wiring layer 500 is arranged on an upper surface rather than the lower surface of the second single crystal semiconductor substrate 210, and the positions of the connection wirings RML (to compare, see, e.g., FIG. 9), the conductive vias RVA (to compare, see, e.g., FIG. 9), and the first through holes TSV1 are different.

The connection wiring layer 500 may be arranged on an upper surface of the second single crystal semiconductor substrate 210. An interlayer insulating layer RINS (see, e.g., FIG. 9) of the connection wiring layer 500 may be arranged on the upper surface of the second single crystal semiconductor substrate 210. While FIG. 9 shows the interlayer insulating layer RINS of the connection wiring layer 500 on the lower surface of the second single crystal semiconductor substrate 210, the present disclosure is not limited thereto, and the interlayer insulating layer RINS of the connection wiring layer 500 on the upper surface of the second single crystal semiconductor substrate 210.

According to one or more embodiments, the plurality of first through holes TSV1 may overlap the driver 100 in the thickness direction, and the first routing wirings RM1 may be electrically connected to the sub-pixels SP1, SP2, and SP3 arranged throughout the display area DAA and may connect the first through hole TSV1 and the sub-pixels SP1, SP2, and SP3 that overlap the driver 100. For example, the connection wirings RML (see, e.g., FIG. 9) of the first routing wirings RM1 may be concentrated in an area where the first through holes TSV1 are arranged, and may connect a terminal connected to each of the sub-pixels SP1, SP2, and SP3 and the conductive via RVA (see, e.g., FIG. 9) arranged in the first through hole TSV1. In the display device 10, the plurality of first through holes TSV1 and the conductive vias RVA (see, e.g., FIG. 9) may each overlap the first single crystal semiconductor substrate 110 in the thickness direction. In contrast, at least a portion of the connection wirings RML (see, e.g., FIG. 9) may not overlap the first single crystal semiconductor substrate 110 in the thickness direction.

As described above, the planar area of the first single crystal semiconductor substrate 110 may be smaller than the planar area of the second single crystal semiconductor substrate 210, and only some of the connection wirings RML (see, e.g., FIG. 9) arranged throughout the second single crystal semiconductor substrate 210 may overlap the first single crystal semiconductor substrate 110 in the thickness direction. Accordingly, the connection wirings RML (see, e.g., FIG. 9) may be arranged throughout the second single crystal semiconductor substrate 210, and ends of the connection wirings RML (see, e.g., FIG. 9) including multiple layers may overlap the first single crystal semiconductor substrate 110 in the thickness direction and may be connected to the plurality of through holes TSV1 and the conductive vias RVA (see, e.g., FIG. 9). The connection wirings RML (see, e.g., FIG. 9) may form a path that electrically connects the light emitting elements arranged on the entire surface of the display area DAA with a larger area to the pixel circuit unit 800 with a relatively small area.

Hereinafter, the structures of the driver 100, the display unit 200, and the connection wiring layer 500 will be described in more detail with further reference to other drawings.

FIG. 9 is a schematic cross-sectional view of a driver, a second single crystal semiconductor substrate of a display unit, and a connection wiring layer according to one or more embodiments of the present disclosure.

Referring to FIG. 9, the driver 100 may include a first single crystal semiconductor substrate 110 and a driving circuit layer 120 arranged thereon.

The first single crystal semiconductor substrate 110 may be a silicon substrate, a germanium substrate, or a silicon-germanium substrate. The first single crystal semiconductor substrate 110 may be a substrate doped with first-type (kind) impurities. A plurality of well areas WA may be arranged on an upper surface of the first single crystal semiconductor substrate 110. The plurality of well areas WA may be areas doped with second-type (kind) impurities. The second-type (kind) impurity may be different from the first-type (kind) impurity described above. For example, if (e.g., when) the first-type (kind) impurity is a p-type (kind) impurity, the second-type (kind) impurity may be an n-type (kind) impurity. In one or more embodiments, if (e.g., when) the first-type (kind) impurity is an n-type (kind) impurity, the second-type (kind) impurity may be a p-type (kind) impurity.

Each of the plurality of well areas WA includes a source area SA corresponding to a source electrode of a first transistor PTR1, a drain area DA corresponding to a drain electrode thereof, and a channel area CH arranged between the source area SA and the drain area DA.

A lower insulating film BINS may be arranged between the gate electrode GE and the well area WA. A side insulating film SINS may be arranged on a side surface of the gate electrode GE. The side insulating film SINS may be arranged on the lower insulating film BINS.

Each of the source area SA and the drain area DA may be an area doped with first-type (kind) impurities. The gate electrode GE of the first transistor PTR1 may overlap the well area WA in the third direction DR3. The channel area CH may overlap the gate electrode GE in the third direction DR3. The source area SA may be arranged on one side of the gate electrode GE, and the drain area DA may be arranged on the other side of the gate electrode GE in a plan view.

Each of the plurality of well areas WA further includes a first low-concentration impurity area LDD1 arranged between the channel area CH and the source area SA and a second low-concentration impurity area LDD2 arranged between the channel area CH and the drain area DA. The first low-concentration impurity area LDD1 may be an area having an impurity concentration lower than that of the source area SA due to the lower insulating film BINS. The second low-concentration impurity area LDD2 may be an area having an impurity concentration lower than that of the drain area DA due to the lower insulating film BINS. A distance between the source area SA and the drain area DA may be increased by the first low-concentration impurity area LDD1 and the second low-concentration impurity area LDD2. Therefore, because a length of the channel area CH of each of the first transistors PTR1 may increase, punch-through and hot carrier phenomena caused by a short channel may be prevented or reduced.

The first single crystal semiconductor substrate 110 may include a plurality of first transistors PTR1 that constitute a plurality of circuit elements of the driver 100. The first transistors PTR1 formed in the first single crystal semiconductor substrate 110 may constitute the driving circuit unit 400, the gate driver 600, the data driver 700, and/or the pixel circuit unit 800.

A process of reducing a thickness of the first single crystal semiconductor substrate 110 may be performed if (e.g., when) the driving circuit layer 120 is formed on the silicon wafer substrate. The first single crystal semiconductor substrate 110 may have a thickness thinner than the wafer substrate on which a semiconductor process for forming the driving circuit layer 120 is performed. In one or more embodiments, the thickness of the first single crystal semiconductor substrate 110 may be 100 μm or less, for example, in the range of 80 μm to 100 μm.

The driving circuit layer 120 may include a first semiconductor insulating layer SINS1, a second semiconductor insulating layer SINS2, a plurality of contact electrodes CTE, a first interlayer insulating layer INS1, a second interlayer insulating layer INS2, a plurality of conductive layers ML1 to ML8, and a plurality of vias VA1 to VA8. The driving circuit layer 120 may include wirings electrically connected to the plurality of first transistors PTR1 included in the first single crystal semiconductor substrate 110.

The first semiconductor insulating layer SINS1 and the second semiconductor insulating layer SINS2 may be arranged on the first single crystal semiconductor substrate 110. The first semiconductor insulating layer SINS1 may be an insulating layer arranged on the first single crystal semiconductor substrate 110, and the second semiconductor insulating layer SINS2 may be an insulating layer arranged on the gate electrode GE of the first transistor PTR1 and the first semiconductor insulating layer SINS1. The first semiconductor insulating layer SINS1 and the second semiconductor insulating layer SINS2 may be formed of a silicon carbon nitride (SiCN) or silicon oxide (SiOₓ, where 0<x≤2)-based inorganic film, but the present disclosure is not limited thereto. It is illustrated in the drawing that the first semiconductor insulating layer SINS1 and the second semiconductor insulating layer SINS2 are each formed as a single layer with a set or predetermined thickness, but the present disclosure is not limited thereto. The first semiconductor insulating layer SINS1 and the second semiconductor insulating layer SINS2 may have a structure in which at least one or more layers are stacked on each other.

The plurality of contact electrodes CTE may be arranged on the first single crystal semiconductor substrate 110. The plurality of contact electrodes CTE may be connected to any one of the gate electrode GE, the source area SA, and/or the drain area DA of each of the first transistors PTR1 formed in the first single crystal semiconductor substrate 110 through holes penetrating through the semiconductor insulating layers SINS1 and SINS2. The plurality of contact electrodes CTE may be formed of any one of copper (Cu), aluminum (Al), tungsten (W), molybdenum (Mo), chromium (Cr), gold (Au), titanium (Ti), nickel (Ni), and neodymium (Nd), and/or an alloy including any one or more thereof. The plurality of contact electrodes CTE may have upper surfaces exposed without being covered by the semiconductor insulating layers SINS1 and SINS2.

The first interlayer insulating layer INS1 may be arranged on the plurality of contact electrodes CTE and the semiconductor insulating layers SINS1 and SINS2. The second interlayer insulating layer INS2 may be arranged on the first interlayer insulating layer INS1. The first interlayer insulating layer INS1 and the second interlayer insulating layer INS2 may be formed of a silicon carbon nitride (SiCN) or silicon oxide (SiOₓ, where 0<x≤2)-based inorganic film, but the present disclosure is not limited thereto. It is illustrated in the drawing that the first interlayer insulating layer INS1 and the second interlayer insulating layer INS2 are each formed as a single layer, but the present disclosure is not limited thereto. The first interlayer insulating layer INS1 and the second interlayer insulating layer INS2 may also have a structure in which at least one or more layers are stacked on each other, and may be arranged between a plurality of first to eighth conductive layers ML1 to ML8, which will be described in more detail later.

The first to eighth conductive layers ML1 to ML8 and the first to eighth vias VA1 to VA8 may be electrically connected to the plurality of contact electrodes CTE and may form the driving circuit unit 400 and/or the data driver 700 of the driver 100. The plurality of first transistors PTR1 formed in the first single crystal semiconductor substrate 110 may be electrically connected to each other through first to eighth conductive layers ML1 to ML8 and the first to eighth vias VA1 to VA8, and may form the driving circuit unit 400 and/or the data driver 700 of the driver 100.

The first conductive layer ML1 may be connected to the contact electrode CTE through the first via VA1. The first conductive layer ML1 may be arranged on the contact electrode CTE, and the first via VA1 may be arranged between the first conductive layer ML1 and the contact electrode CTE and may be in contact with the first conductive layer ML1 and the contact electrode CTE, respectively. The second conductive layer ML2 may be connected to the first conductive layer ML1 through the second via VA2. The second conductive layer ML2 may be arranged on the first conductive layer ML1, and the second via VA2 may be arranged between the first conductive layer ML1 and the second conductive layer ML2 and may be in contact with both the first conductive layer ML1 and the second conductive layer ML2.

The third conductive layer ML3 may be connected to the second conductive layer ML2 through the third via VA3. The fourth conductive layer ML4 may be connected to the third conductive layer ML3 through the fourth via VA4, the fifth conductive layer ML5 may be connected to the fourth conductive layer ML4 through the fifth via VA5, and the sixth conductive layer ML6 may be connected to the fifth conductive layer ML5 through the sixth via VA6. The third conductive layer ML3, the fourth conductive layer ML4, the fifth conductive layer ML5, and the sixth conductive layer ML6 may be sequentially arranged on the second conductive layer ML2, and the third via VA3, the fourth via VA4, the fifth via VA5, and the sixth via VA6 may be arranged between the third conductive layer ML3, the fourth conductive layer ML4, the fifth conductive layer ML5, and the sixth conductive layer ML6, respectively. The third to sixth vias VA3 to VA6 may be in contact with different metal layers arranged above and below the third to sixth vias VA3 to VA6, respectively. The seventh via VA7 may be arranged on the sixth conductive layer ML6. The seventh via VA7 may be in contact with both the seventh conductive layer ML7 and the sixth conductive layer ML6 arranged thereon.

The first to sixth conductive layers ML1 to ML6 and the first to seventh vias VA1 to VA7 may be arranged in the first interlayer insulating layer INS1. The first to sixth conductive layers ML1 to ML6 and the first to seventh vias VA1 to VA7 may constitute a first driving circuit layer of the driving circuit layer 120 arranged in the first interlayer insulating layer INS1.

The seventh conductive layer ML7 may be connected to the sixth conductive layer ML6 through the seventh via VA7. The seventh conductive layer ML7 may be arranged on the first interlayer insulating layer INS1 and the sixth conductive layer ML6, and the seventh via VA7 may be arranged between the sixth conductive layer ML6 and the seventh conductive layer ML7 and may be in contact with both the sixth conductive layer ML6 and the seventh conductive layer ML7. The eighth conductive layer ML8 may be connected to the seventh conductive layer ML7 through the eighth via VA8. The eighth conductive layer ML8 may be arranged on the seventh conductive layer ML7, and the eighth via VA8 may be arranged between the seventh conductive layer ML7 and the eighth conductive layer ML8 and may be in contact with both the seventh conductive layer ML7 and the eighth conductive layer ML8. The eighth conductive layer ML8 may have an upper surface exposed without being covered by the second interlayer insulating layer INS2, and may be electrically connected to the routing wiring RM (e.g., first routing wiring RM1 and/or second routing wiring RM2) arranged in the display unit 200 described above.

The seventh conductive layer ML7, the eighth via VA8, and the eighth conductive layer ML8 may be arranged in the second interlayer insulating layer INS2. The seventh conductive layer ML7, the eighth via VA8, and the eighth conductive layer ML8 may constitute a second driving circuit layer of the driving circuit layer 120 arranged in the second interlayer insulating layer INS2.

It is illustrated in the drawing that the first to eighth conductive layers ML1 to ML8 and the first to eighth vias VA1 to VA8 have a structure in which the first to eighth conductive layers ML1 to ML8 and the first to eighth vias VA1 to VA8 are stacked on each other, but the arrangement and connection thereof may be variously modified depending on the circuits of the driving circuit unit 400 and the data driver 700 of the driver 100. The connection structure illustrated in the drawing is only an example, and the connection of the driving circuit layer 120 arranged in the driver 100 of the display device 10 is not limited thereto. In one or more embodiments, the driving circuit layer 120 may not necessarily include the first to eighth conductive layers ML1 to ML8 and the first to eighth vias VA1 to VA8, and some of these layers may not be provided or a larger number of layers may be arranged.

The first to eighth conductive layers ML1 to ML8 and the first to eighth vias VA1 to VA8 may be formed of substantially the same material. For example, the first to eighth conductive layers ML1 to ML8 and the first to eighth vias VA1 to VA8 may be formed of any one of copper (Cu), aluminum (Al), tungsten (W), molybdenum (Mo), chromium (Cr), gold (Au), titanium (Ti), nickel (Ni), and neodymium (Nd), and/or an alloy including any one or more thereof.

Each of a thickness of the first conductive layer ML1, a thickness of the second conductive layer ML2, a thickness of the third conductive layer ML3, a thickness of the fourth conductive layer ML4, a thickness of the fifth conductive layer ML5, and a thickness of the sixth conductive layer ML6 may be greater than each of a thickness of the first via VA1, a thickness of the second via VA2, a thickness of the third via VA3, a thickness of the fourth via VA4, a thickness of the fifth via VA5, and a thickness of the sixth via VA6. In other words, the thickness of each of the first to sixth conductive layers ML1-ML6 is greater than the thickness of each of the first to sixth via layers VA1-VA6. Each of the thickness of the second conductive layer ML2, the thickness of the third conductive layer ML3, the thickness of the fourth conductive layer ML4, the thickness of the fifth conductive layer ML5, and the thickness of the sixth conductive layer ML6 may be greater than the thickness of the first conductive layer ML1. In other words, the thickness of each of the second through sixth conductive layers ML2-ML6 is greater than the thickness of the first conductive layer ML1. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be substantially the same. For example, the thickness of the first conductive layer ML1 may be about (approximately) 1360 Å, each of the thickness of the second conductive layer ML2, the thickness of the third conductive layer ML3, the thickness of the fourth conductive layer ML4, the thickness of the fifth conductive layer ML5, and the thickness of the sixth conductive layer ML6 may be about (approximately) 1440 Å (e.g., the second to sixth conductive layers ML2-ML6 may each have a thickness of 1440 Å), and each of the thickness of the first via VA1, the thickness of the second via VA2, the thickness of the third via VA3, the thickness of the fourth via VA4, the thickness of the fifth via VA5, and the thickness of the sixth via VA6 may be 1150 Å (e.g., the first to sixth via layers VA1-VA6 may each have a thickness of 1150 Å).

Each of a thickness of the seventh conductive layer ML7 and a thickness of the eighth conductive layer ML8 may be greater than each of the thickness of the first conductive layer ML1, the thickness of the second conductive layer ML2, the thickness of the third conductive layer ML3, the thickness of the fourth conductive layer ML4, the thickness of the fifth conductive layer ML5, and the thickness of the sixth conductive layer ML6. In other words, the seventh and eighth conductive layers ML7-ML8 are each thicker than each of the first to sixth conductive layers ML1-ML6. Each of the thickness of the seventh conductive layer ML7 and the thickness of the eighth conductive layer ML8 may be greater than each of a thickness of the seventh via VA7 and a thickness of the eighth via VA8. Each of the thickness of the seventh via VA7 and the thickness of the eighth via VA8 may be greater than each of the thickness of the first via VA1, the thickness of the second via VA2, the thickness of the third via VA3, the thickness of the fourth via VA4, the thickness of the fifth via VA5, and the thickness of the sixth via VA6. In other words, the seventh and eighth via layers VA7-VA8 are each thicker than each of the first to sixth via layers VA1-VA6. The thickness of the seventh conductive layer ML7 and the thickness of the eighth conductive layer ML8 may be substantially the same. For example, each of the thickness of the seventh conductive layer ML7 and the thickness of the eighth conductive layer ML8 may be about (approximately) 9000 Å (e.g., the seventh and eighth conductive layers ML7-ML8 may each have a thickness of 9000 Å). Each of the thicknesses of the seventh via VA7 and the eighth via VA8 may be about (approximately) 6000 Å (e.g., the seventh and eighth via layers VA7-VA8 may each have a thickness of 6000 Å).

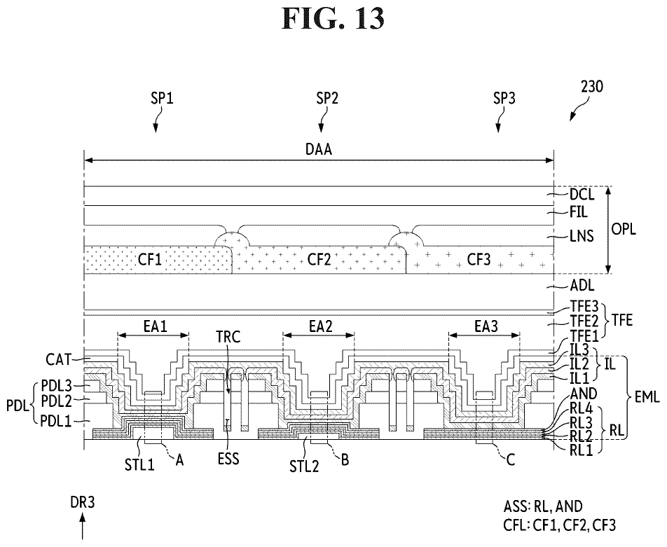

The display unit 200 may include a second single crystal semiconductor substrate 210. The second single crystal semiconductor substrate 210 may be a silicon substrate, a germanium substrate, or a silicon-germanium substrate. The second single crystal semiconductor substrate 210 may be a substrate doped with impurities. Unlike the first single crystal semiconductor substrate 110, transistors may not be formed on the second single crystal semiconductor substrate 210. The second single crystal semiconductor substrate 210 may serve as a lower substrate on which a display element layer EML (see, e.g., FIG. 13) is arranged, and may form a connection path on which the first routing wiring RM1 that electrically connects the light emitting element of the display element layer EML (see, e.g., FIG. 13) and the pixel circuit unit 800 of the driver 100 is arranged. In other words, the second single crystal semiconductor substrate 210 may form a connection path (e.g., first through holes TSV1 and conductive vias RVA) electrically connecting the first routing wiring RM1 to the light emitting element of the display element layer EML.

As described above, the first single crystal semiconductor substrate 110 of the driver 100 may have a smaller planar area than the second single crystal semiconductor substrate 210 of the display unit 200, and may have small-sized elements arranged with a high degree of integration, thereby reducing power consumption and improving manufacturing yield. In contrast, a process having a larger planar area and a relatively larger line width than the first single crystal semiconductor substrate 110 may be performed on the second single crystal semiconductor substrate 210 of the display unit 200. Unlike the circuit elements formed on the first single crystal semiconductor substrate 110, the elements of the display layer 230 formed on the second single crystal semiconductor substrate 210 may not require a high degree of integration. Accordingly, a semiconductor process performed on the first wafer substrate may be performed as a high-cost process with a small line width, and a semiconductor process performed on the second wafer substrate may be performed as a low-cost process with a relatively large line width.

The second single crystal semiconductor substrate 210 may include a plurality of first through holes TSV1 spaced and/or apart (e.g., spaced apart or separated) from each other. The first through hole TSV1 may penetrate from an upper surface to a lower surface of the second single crystal semiconductor substrate 210. The conductive vias RVA of the first routing wiring RM1 may be arranged in the first through holes TSV1. The first through hole TSV1 may form a connection path for the first routing wirings RM1 that electrically connect the pixel circuit unit 800 of the driver 100 and the light emitting element of the display unit 200.

In one or more embodiments, the second single crystal semiconductor substrate 210 may include a plurality of second through holes TSV2 formed in the non-display area NA, and conductive vias of the second routing wiring RM2 may each be arranged in the second through holes TSV2. The circuit board 300 and the signal terminal STD of the driver 100 may be electrically connected to each other through the second routing wiring RM2.

In one or more embodiments, the first through hole TSV1 of the second single crystal semiconductor substrate 210 may be formed through a through silicon via (TSV) process that forms a hole penetrating through the wafer substrate. The display layer 230 and the driver 100 may be electrically connected to each other without a separate wire through the through hole TSV1 and the first routing wiring RM1 formed in the second single crystal semiconductor substrate 210.

A process of reducing a thickness of the second single crystal semiconductor substrate 210 may be performed after the driver 100 is formed on the silicon wafer substrate. The second single crystal semiconductor substrate 210 may have a thickness thinner than the wafer substrate on which a process for forming the conductive layers is performed. In one or more embodiments, the thickness of the second single crystal semiconductor substrate 210 may be 100 μm or less, for example, in the range of 80 μm to 100 μm.

The connection wiring layer 500 may be arranged on a lower surface of the second single crystal semiconductor substrate 210. The connection wiring layer 500 may include an interlayer insulating layer RINS and a plurality of connection wirings RML.

The interlayer insulating layer RINS may be arranged on the lower surface of the second single crystal semiconductor substrate 210. The interlayer insulating layer RINS may be formed of a silicon carbon nitride (SiCN) or silicon oxide (SiOₓ, 0<x≤2)-based inorganic film, but the present disclosure is not limited thereto. It is illustrated in the drawing that the interlayer insulating layer RINS is formed of one layer, but the present disclosure is not limited thereto and the interlayer insulating layer RINS may have a structure in which at least one or more layers are stacked on each other, and these may be arranged between the connection wirings RML.

The connection wirings RML may form the routing wirings RM1 and RM2 together with the conductive via RVA. The connection wiring RML may include at least one or more conductive layers and one or more vias connecting the conductive layers to each other. The connection and structure of the connection wirings RML may be the same as the description of the plurality of conductive layers ML1 to ML8 and vias VA1 to VA8 described above. The connection wirings RML may be connected to the light emitting elements of the sub-pixels SP1, SP2, and SP3 or the circuit board 300 through the conductive vias RVA arranged in the through holes TSV1 and TSV2 of the second single crystal semiconductor substrate 210, and may each electrically connect the light emitting elements or the circuit board 300 to the driving circuit layer 120 of the driver 100.

The conductive vias RVA of the first routing wirings RM1 may be arranged in the first through holes TSV1. The conductive vias RVA of the first routing wirings RM1 may be arranged in the first through holes TSV1 from the lower surface of the reflective electrode layer RL (see, e.g., FIG. 13), which will be described in more detail later, to the lower surface of the second single crystal semiconductor substrate 210. The conductive vias RVA may be electrically connected to the first electrode AND (see, e.g., FIG. 13) arranged in each sub-pixel SP1, SP2, and SP3 through the reflective electrode layer RL (see, e.g., FIG. 13). The conductive vias RVA may be connected to both the reflective electrode layer RL (see, e.g., FIG. 13) and the connection wirings RML, and the connection wirings RML may be connected to the pixel circuit unit 800. The connection wirings RML may include wirings illustrated on the rear surface of the display unit 200 in FIG. 7 (see, e.g., first routing wirings RM1). The first routing wiring RM1 may connect the light emitting element of each sub-pixel SP1, SP2, and SP3 to the pixel circuit unit 800 of the driver 100.

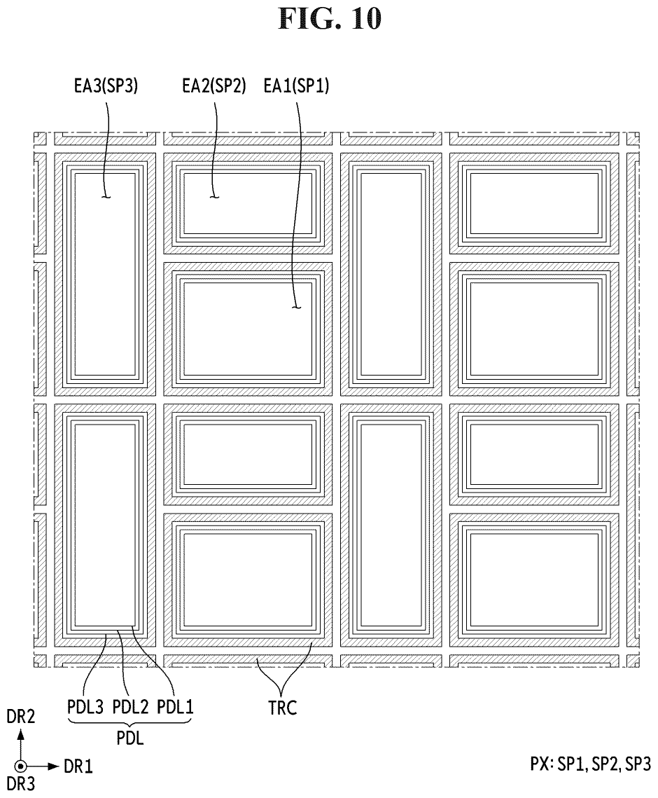

FIG. 10 is a plan view illustrating first electrodes, light emitting areas, and a pixel defining film of a plurality of sub-pixels arranged in a display area of the display unit, according to one or more embodiments of the present disclosure.

Referring to FIG. 10, each of a plurality of pixels PX may include a first sub-pixel SP1, a second sub-pixel SP2, and a third sub-pixel SP3. The first to third sub-pixels SP1, SP2, and SP3 may include light emitting areas EA1, EA2, and EA3, respectively. For example, the first sub-pixels SP1 may include first light emitting areas EA1, the second sub-pixels SP2 may include second light emitting areas EA2, and the third sub-pixels SP3 may include third light emitting areas EA3.

Each of the first light emitting areas EA1, the second light emitting areas EA2, and the third light emitting areas EA3 may have a quadrangular planar shape such as a rectangle, a square, or a rhombus. For example, the first light emitting areas EA1 may each have a rectangular planar shape having a short side in the first direction DR1 and a long side in the second direction DR2. In one or more embodiments, each of the second light emitting areas EA2 and the third light emitting areas EA3 may have a rectangular planar shape having a long side in the first direction DR1 and a short side in the second direction DR2.

Each of the first light emitting areas EA1, the second light emitting areas EA2, and the third light emitting areas EA3 may be an area defined by the pixel defining film PDL. For example, each of the first light emitting areas EA1, the second light emitting areas EA2, and the third light emitting areas EA3 may be an area defined by a first pixel defining film PDL1.

A length of each of the third light emitting areas EA3 in the first direction DR1 may be smaller (less) than a length of each of the first light emitting areas EA1 in the first direction DR1, and may be smaller (less) than a length of each of the second light emitting areas EA2 in the first direction DR1. The length of each of the first light emitting areas EA1 in the first direction DR1 and the length of each of the second light emitting areas EA2 in the first direction DR1 may be substantially the same.

In each of the plurality of pixels PX, the first light emitting area EA1 and the second light emitting area EA2 may be adjacent to each other in the second direction DR2. In one or more embodiments, the first light emitting area EA1 and the third light emitting area EA3 may be adjacent to each other in the first direction DR1. In one or more embodiments, the second light emitting area EA2 and the third light emitting area EA3 may be adjacent to each other in the first direction DR1. An area of the first light emitting area EA1, an area of the second light emitting area EA2, and an area of the third light emitting area EA3 may be different.

It is illustrated in the drawing that each of the first light emitting area EA1, the second light emitting area EA2, and the third light emitting area EA3 has a quadrangular planar shape, but the present disclosure is not limited thereto. For example, each of the first light emitting area EA1, the second light emitting area EA2, and the third light emitting area EA3 may have a polygonal, circular, or elliptical planar shape other than the quadrangular shape.

Each first light emitting area EA1 emits light of a first color, each second light emitting area EA2 emits light of a second color, and each third light emitting area EA3 emits light of a third color. Here, the light of the first color may be light in a red wavelength band, the light of the second color may be light in a green wavelength band, and the light of the third color may be light in a blue wavelength band. For example, the blue wavelength band may indicate that a main peak wavelength of light is included in a wavelength band of about (approximately) 370 nm to about 460 nm, the green wavelength band may indicate that a main peak wavelength of light is included in a wavelength band of about (approximately) 480 nm to about 560 nm, and the red wavelength band may indicate that a main peak wavelength of light is included in a wavelength band of about (approximately) 600 nm to about 750 nm.

At least one trench TRC may be a structure for disconnecting at least one charge generation layer of a light emitting stack IL (see, e.g., FIG. 13), which will be described in more detail later, between the light emitting areas EA1, EA2, and EA3 adjacent to each other. For each pixel PX, at least one trench TRC may be arranged between the first light emitting area EA1 and the second light emitting area EA2, between the first light emitting area EA1 and the third light emitting area EA3, and between the second light emitting area EA2 and the third light emitting area EA3.

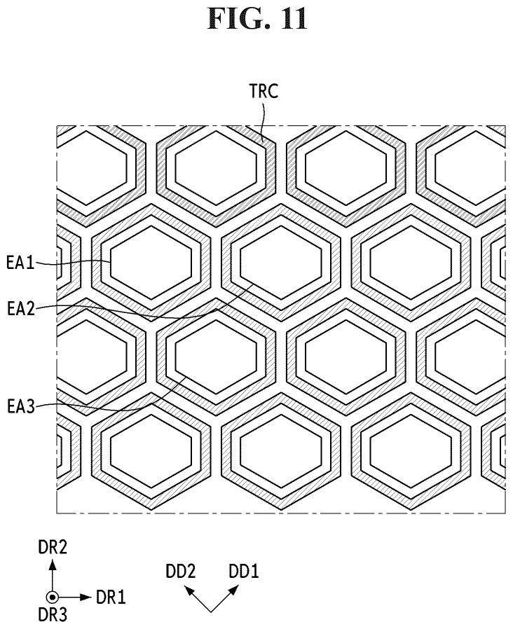

FIG. 11 is a plan view illustrating first electrodes, light emitting areas, and a pixel defining film of a plurality of sub-pixels arranged in a display area of the display unit, according to one or more embodiments of the present disclosure.

Referring to FIG. 11, because one or more embodiments of FIG. 11 are substantially the same as the embodiments of FIG. 10, except that the planar shapes of the first light emitting area EA1, the second light emitting area EA2, and the third light emitting area EA3 are different from the embodiments of FIG. 10, the descriptions that are substantially the same or similar to the embodiments of FIG. 10 may not be provided.

For each pixel PX, the first light emitting area EA1, the second light emitting area EA2, and the third light emitting area EA3 may each be arranged in a hexagonal structure having a hexagonal planar shape. In such embodiments, the first light emitting area EA1 and the second light emitting area EA2 are adjacent to each other in the first direction DR1, but the second light emitting area EA2 and the third light emitting area EA3 may be adjacent to each other in a first diagonal direction DD1, and the first light emitting area EA1 and the third light emitting area EA3 may be adjacent to each other in a second diagonal direction DD2. The first diagonal direction DD1, which is a direction between the first direction DR1 and the second direction DR2, may indicate a direction inclined by 45 degrees compared to the first direction DR1 and the second direction DR2, and the second diagonal direction DD2 may be a direction normal (e.g., perpendicular) to the first diagonal direction DD1.

It is illustrated in FIGS. 10 and 11 that each of the plurality of pixels PX includes three light emitting areas EA1, EA2, and EA3, but the present disclosure is not limited thereto. For example, each of the plurality of pixels PX may also include four light emitting areas.

In addition, the arrangement of the light emitting areas of the plurality of pixels PX is not limited to that illustrated in the drawings. For example, the light emitting areas of the plurality of pixels PX may be arranged in a stripe structure in which the light emitting areas are arranged in the first direction DR1, a PENTILE® (for example, an RGBG matrix, an RGBG structure, or RGBG matrix structure) or a diamond (Diamond Pixel™) (e.g., a display (e.g., an OLED display) containing red, blue, and green (RGB) light emitting regions arranged in the shape of diamonds,, or a hexagonal structure in which light emitting areas having a hexagonal planar shape are arranged. PENTILE® is a duly registered trademark of Samsung Display Co., Ltd. Diamond Pixel® is a duly registered trademark of Samsung Display Co., Ltd.

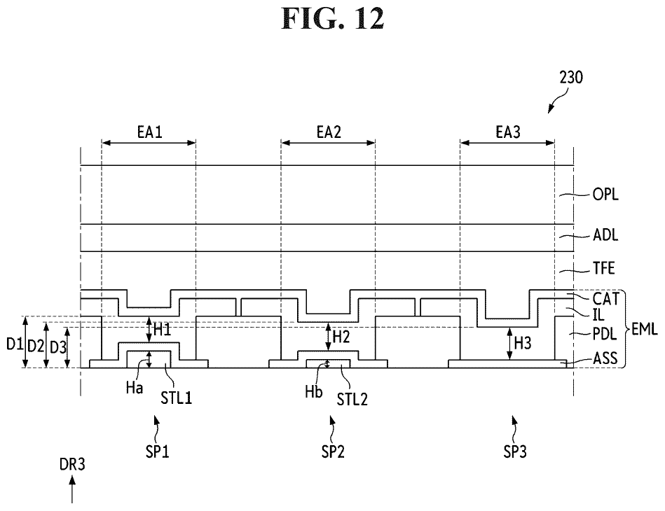

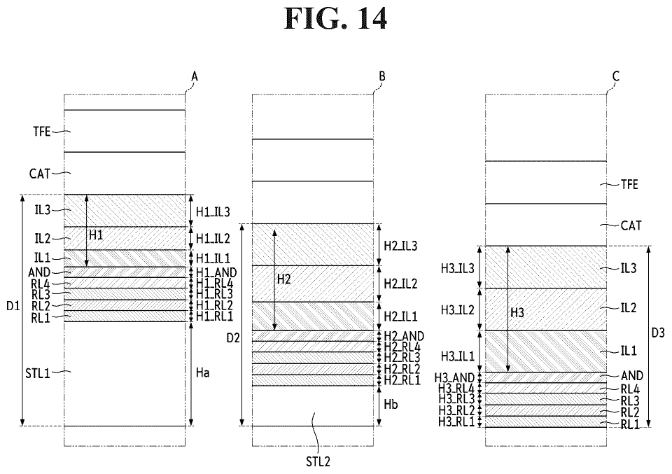

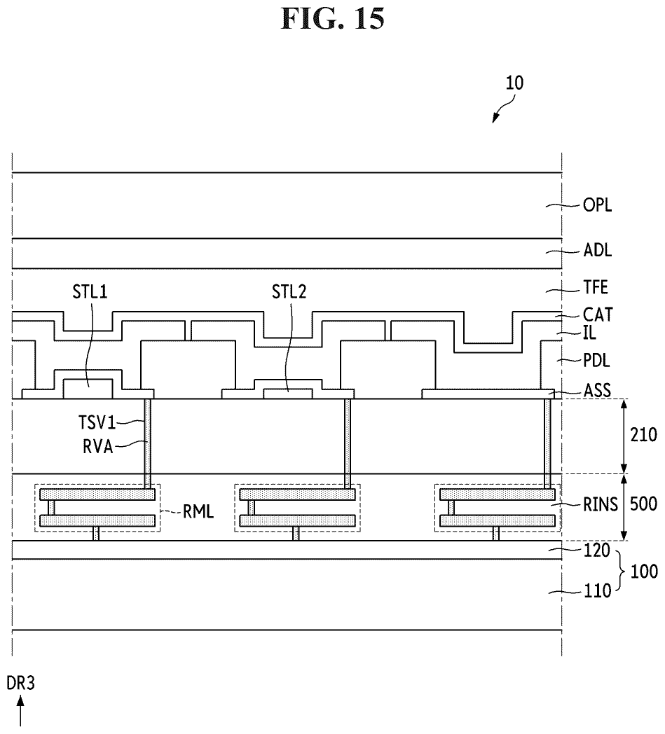

FIG. 12 is a schematic cross-section view illustrating a portion of a display layer according to one or more embodiments of the present disclosure. FIG. 13 is a cross-section view illustrating a portion of the display layer according to one or more embodiments of the present disclosure. FIG. 14 is an enlarged view of areas A, B, and C of FIG. 13, according to one or more embodiments of the present disclosure. FIG. 15 is a schematic cross-sectional view of the display device, according to one or more embodiments of the present disclosure.

Referring to FIGS. 12 to 15 in addition to FIGS. 6 and 7, the display layer 230 may be arranged on the second single crystal semiconductor substrate 210. The display layer 230 may include light emitting elements electrically connected to the driver 100 and to emit light. The display layer 230 may include a display element layer EML, an encapsulation layer TFE, an adhesive layer ADL, and an optical layer OPL. In one or more embodiments, the display layer 230 may further include a polarizing plate arranged on the optical layer OPL.

The display element layer EML may be arranged on the second single crystal semiconductor substrate 210. The display element layer EML may include light emitting elements each including an electrode assembly ASS, a light emitting stack IL, a second electrode CAT, a pixel defining film PDL, and a plurality of trenches TRC. The electrode assembly ASS may include a reflective electrode layer RL and a first electrode AND.

Each of the reflective electrode layers RL may be arranged on the second single crystal semiconductor substrate 210. Each of the reflective electrode layers RL may include at least one or more reflective electrodes RL1, RL2, RL3, and RL4. For example, each of the reflective electrode layers RL may include first to fourth reflective electrodes RL1, RL2, RL3, and RL4, as illustrated, for example, in FIG. 13.

Each of the first reflective electrodes RL1 may be arranged on the second single crystal semiconductor substrate 210 and may be connected to the conductive vias RVA arranged in the first through holes TSV1. The first reflective electrodes RL1 may be formed of any one of copper (Cu), aluminum (Al), tungsten (W), molybdenum (Mo), chromium (Cr), gold (Au), titanium (Ti), nickel (Ni), and/or neodymium (Nd), or an alloy including any one thereof. For example, the first reflective electrode RL1 of each of the light emitting elements may include titanium nitride (TiN).

Each of second reflective electrodes RL2 may be arranged on each of the first reflective electrodes RL1, respectively. The second reflective electrodes RL2 may be formed of any one of copper (Cu), aluminum (Al), tungsten (W), molybdenum (Mo), chromium (Cr), gold (Au), titanium (Ti), nickel (Ni), and/or neodymium (Nd), or an alloy including any one thereof. For example, the second reflective electrode RL2 of each of the light emitting elements may include aluminum (Al).

Each of third reflective electrodes RL3 may be arranged on each of the second reflective electrodes RL2, respectively. The third reflective electrodes RL3 may be formed of any one of copper (Cu), aluminum (Al), tungsten (W), molybdenum (Mo), chromium (Cr), gold (Au), titanium (Ti), nickel (Ni), and/or neodymium (Nd), or an alloy including any one thereof. For example, the third reflective electrodes RL3 of each of the light emitting elements may include titanium nitride (TiN).

Each of fourth reflective electrodes RL4 may be arranged on each of the third reflective electrodes RL3, respectively. The fourth reflective electrodes RL4 may be formed of any one of copper (Cu), aluminum (Al), tungsten (W), molybdenum (Mo), chromium (Cr), gold (Au), titanium (Ti), nickel (Ni), and/or neodymium (Nd), or an alloy including any one thereof. For example, the fourth reflective electrode RL4 of each of the light emitting elements may include titanium (Ti).

Each of the second reflective electrodes RL2 may be an electrode that substantially reflects light from the light emitting elements, and a thickness of each of the second reflective electrodes RL2 may be greater than a total thickness of a corresponding first reflective electrode RL1, a corresponding third reflective electrode RL3, and a corresponding the fourth reflective electrode RL4, where “corresponding” refers to first, third and fourth reflective electrodes RL11, RL3, RL4 in the same pixel as the second reflective electrode RL2. For example, the thickness of the first reflective electrode RL1, the thickness of the third reflective electrode RL3, and the thickness of fourth reflective electrode RL4 are each about (approximately) 100 Å, and the thickness of the second reflective electrode RL2 may be about (approximately) 850 Å.

The first electrode AND (e.g., pixel electrode) of each of the light emitting elements may be arranged on the corresponding reflective electrode layer RL, where “corresponding” refers to the reflective electrode layer RL in the same pixel as the first electrode AND. The first electrode AND of each of the light emitting elements may be in direct contact with the corresponding reflective electrode layer RL. The first electrode AND of each of the light emitting elements LE may be connected to the pixel circuit unit 800 through the first to fourth reflective electrodes RL1 to RL4 and the first routing wirings RM1. The first electrode AND of each of the light emitting elements may be formed of any one of copper (Cu), aluminum (Al), tungsten (W), molybdenum (Mo), chromium (Cr), gold (Au), titanium (Ti), nickel (Ni), and/or neodymium (Nd), or an alloy including any one thereof. For example, the first electrode AND of each of the light emitting elements may be formed of titanium nitride (TiN).

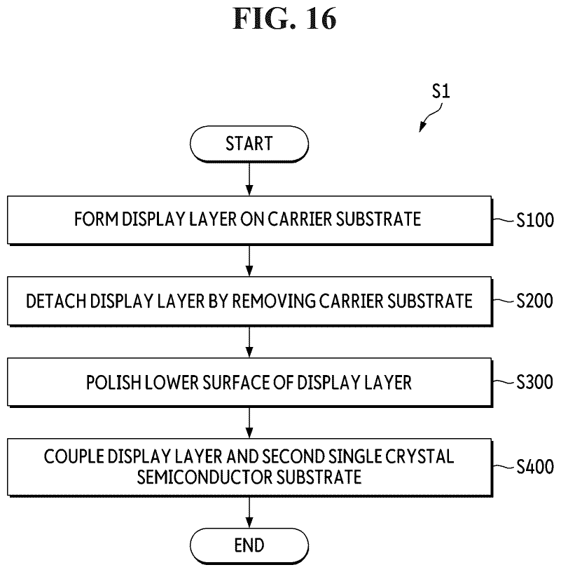

The display device 10 according to one or more embodiments may further include step layers STL1 and STL2 arranged below the electrode assembly ASS. The step layers STL1 and STL2 may be arranged on the second single crystal semiconductor substrate 210. For convenience of explanation, the step layers STL1 and STL2 are illustrated together with the display layer 230 in the drawing, but as will be described in more detail later with reference to FIG. 16 and/or the like, the step layers STL1 and STL2 may be formed on the second single crystal semiconductor substrate 210 and then coupled to the display layer 230 in a process of coupling the second single crystal semiconductor substrate 210 and the display layer 230.

The step layers STL1 and STL2 may be layers for adjusting a resonance distance of light emitted from the light emitting elements. The step layers STL1 and STL2 may be arranged in at least one of the first sub-pixel SP1, the second sub-pixel SP2, and/or the third sub-pixel SP3. In one or more embodiments, the step layers STL1 and STL2 may include a first step layer STL1 and a second step layer STL2.

For example, the first step layer STL1 may be arranged in the first sub-pixel SP1 (e.g., each of the first sub-pixels SP1), and may be arranged below the electrode assembly ASS of the first sub-pixel SP1 (e.g., each of the first sub-pixels SP1). The second step layer STL2 may be arranged in the second sub-pixel SP2 (e.g., each of the second sub-pixels SP2), and may be arranged below the electrode assembly ASS of the second sub-pixel SP2 (e.g., each of the second sub-pixels SP2). The step layers STL1 and STL2 may not be arranged in the third sub-pixel SP3 (e.g., the third sub-pixels SP3), and the electrode assembly ASS of the third sub-pixel SP3 (e.g., the third sub-pixels SP3) may be directly arranged on the second single crystal semiconductor substrate 210.

The first step layer STL1 may at least partially overlap the electrode assembly ASS of the first sub-pixel SP1. The upper and side surfaces of the first step layer STL1 may be covered by the electrode assembly ASS of the first sub-pixel SP1. A shape of the electrode assembly ASS of the first sub-pixel SP1 may conform to the shape of the upper and side surfaces of the first step layer STL1. For example, the electrode assembly ASS of the first sub-pixel SP1 may protrude in the third direction DR3 along the side surfaces of the first step layer STL1 at a portion in contact with the first step layer STL1, may be in contact with the upper surface of the first step layer STL1 in a direction perpendicular to the third direction DR3 between the side surfaces of the first step layer STL1, and may be in contact with the upper surface of the second single crystal semiconductor substrate 210 at a portion that is not in contact with the first step layer STL1. The electrode assembly ASS of the first sub-pixel SP1 may be connected to the conductive via RVA on the upper surface of the second single crystal semiconductor substrate 210. While the above refers to the first sub-pixel SP1 and its components in the singular, the same may apply to each of the first sub-pixels SP1 throughout the display layer 230.

The second step layer STL2 may at least partially overlap the electrode assembly ASS of the second sub-pixel SP2. The upper and side surfaces of the second step layer STL2 may be covered by the electrode assembly ASS of the second sub-pixel SP2. A shape of the electrode assembly ASS of the second sub-pixel SP2 may conform to the shape of the upper and side surfaces of the second step layer STL2. For example, the electrode assembly ASS of the second sub-pixel SP2 may protrude in the third direction DR3 along the side surfaces of the second step layer STL2 at a portion in contact with the second step layer STL2, may be in contact with the upper surface of the second step layer STL2 in a direction perpendicular to the third direction DR3 between the side surfaces of the second step layer STL2, and may be in contact with the upper surface of the second single crystal semiconductor substrate 210 at a portion that is not in contact with the second step layer STL2. The electrode assembly ASS of the second sub-pixel SP2 may be connected to the conductive via RVA on the upper surface of the second single crystal semiconductor substrate 210. While the above refers to the second sub-pixel SP2 and its components in the singular, the same may apply to each of the second sub-pixels SP2 throughout the display layer 230.

In one or more embodiments, the electrode assembly ASS of each of the third sub-pixels SP3 may have a flat shape. For example, an entirety of a lower surface of the electrode assembly ASS of each of the third sub-pixels SP3 may be in contact with the second single crystal semiconductor substrate 210.

In one or more embodiments, both ends of the electrode assembly ASS for each pixel may at least partially overlap the pixel defining film PDL. For example, both ends of the electrode assembly ASS may be at least partially covered by the pixel defining film PDL. Accordingly, in a method (S1) (see, e.g., FIG. 16) for manufacturing a display device described in more detail later, if (e.g., when) the display layer 230 is coupled to the second single crystal semiconductor substrate 210, both ends of the electrode assembly ASS may be fixed by the pixel defining film PDL, even if the shape of the electrode assembly ASS changes due to the first step layer STL1 and the second step layer STL2. Therefore, both ends of the electrode assembly ASS may be stably connected to the conductive via RVA.

The distances H1, H2, and H3 between the second electrode CAT and the electrode assembly ASS in each of the first sub-pixel SP1, the second sub-pixel SP2, and the third sub-pixel SP3 may be different. In order to adjust the distances H1, H2, and H3 between the second electrode CAT and the electrode assembly ASS according to the main wavelength of light emitted from each of the first sub-pixel SP1, the second sub-pixel SP2, and the third sub-pixel SP3, the presence or absence of the step layers STL1 and STL2 and the thicknesses Ha and Hb of the step layers STL1 and STL2 in each of the first sub-pixel SP1, the second sub-pixel SP2, and the third sub-pixel SP3 may be set.

For example, in FIG. 12, the thickness Ha of the first step layer STL1 may be greater than the thickness Hb of the second step layer STL2. Accordingly, the distance H1 between the second electrode CAT and the electrode assembly ASS in the first sub-pixel SP1 may be smaller (less) than the distance H2 between the second electrode CAT and the electrode assembly ASS in the second sub-pixel SP2 and the distance H3 between the second electrode CAT and the electrode assembly ASS in the third sub-pixel SP3, and the distance H2 between the second electrode CAT and the electrode assembly ASS in the second sub-pixel SP2 may be smaller (less) than the distance H3 between the second electrode CAT and the electrode assembly ASS in the third sub-pixel SP3. However, the present disclosure is not limited thereto. The distances H1, H2, and H3 between the second electrode CAT and the electrode assembly ASS in each sub-pixel SP1, SP2, and SP3 may be modified and designed in one or more suitable ways.

In one or more embodiments, as illustrated in FIGS. 12 and 14, in each of the first sub-pixel SP1, the second sub-pixel SP2, and the third sub-pixel SP3, distances D1, D2, and D3 between the lower surface of the display element layer EML (or the upper surface of the second single crystal semiconductor substrate 210) and the lower surface of the second electrode CAT may be different.

For example, the distance D1 between the lower surface of the display element layer EML and the lower surface of the second electrode CAT in the first sub-pixel SP1 may be greater than the distance D2 between the lower surface of the display element layer EML and the lower surface of the second electrode CAT in the second sub-pixel SP2 and the distance D3 between the lower surface of the display element layer EML and the lower surface of the second electrode CAT in the third sub-pixel SP3, and the distance D2 between the lower surface of the display element layer EML and the lower surface of the second electrode CAT in the second sub-pixel SP2 may be greater than the distance D3 between the lower surface of the display element layer EML and the lower surface of the second electrode CAT in the third sub-pixel SP3.

This is because the light emitting stack IL moves together in the third direction DR3 in a process of forming the electrode assembly ASS protruding in the third direction DR3 due to the first step layer STL1 and the second step layer STL2, when the display layer 230 is coupled to the second single crystal semiconductor substrate 210 in a method (S1) (see, e.g., FIG. 16) for manufacturing a display device described in more detail later. For example, in the first sub-pixel SP1 and the second sub-pixel SP2, the light emitting stack IL slightly moves in the third direction DR3 due to the first step layer STL1 and the second step layer STL2, so that the distances D1 and D2 between the lower surface of the display element layer EML and the lower surface of the second electrode CAT may increase.

If (e.g., when) the distances D1 and D2 between the lower surface of the display element layer EML and the lower surface of the second electrode CAT in the first sub-pixel SP1 and the second sub-pixel SP2 increase as much as the thicknesses Ha and Hb of the first step layer STL1 and the second step layer STL2 compared to the distance D3 between the lower surface of the display element layer EML and the lower surface of the second electrode CAT in the third sub-pixel SP3, the distances H1, H2, and H3 between the second electrode CAT and the electrode assembly ASS in each of the first sub-pixel SP1, the second sub-pixel SP2, and the third sub-pixel SP3 eventually become the same, which makes it impossible to keep the resonance distance different.

However, as the electrode assembly ASS and the light emitting stack IL are compressed in the third direction DR3 due to elasticity of the electrode assembly ASS and the light emitting stack IL, a thickness of each component layer of the electrode assembly ASS and the light emitting stack IL in the first to third sub-pixels SP1, SP2, and SP3 may be formed to be different from each other. For example, because the thickness Ha of the first step layer STL1 is greater than the thickness Hb of the second step layer STL2, a compressive force applied to the electrode assembly ASS and the light emitting stack IL of the first sub-pixel SP1 by the first step layer STL1 may be greater than a compressive force applied to the electrode assembly ASS and the light emitting stack IL of the second sub-pixel SP2 by the second step layer STL2. Accordingly, even if the distance D1 between the lower surface of the display element layer EML and the lower surface of the second electrode CAT in the first sub-pixel SP1 and the distance D2 between the lower surface of the display element layer EML and the lower surface of the second electrode CAT in the second sub-pixel SP2 increase, the distance H1 between the second electrode CAT and the electrode assembly ASS in the first sub-pixel SP1 may be smaller (less) than the distance H2 between the second electrode CAT and the electrode assembly ASS in the second sub-pixel SP2, and the distance H2 between the second electrode CAT and the electrode assembly ASS in the second sub-pixel SP2 may be smaller (less) than the distance H3 between the second electrode CAT and the electrode assembly ASS in the third sub-pixel SP3.

For example, a thickness H1_RL1 of the first reflective electrode RL1 in the first sub-pixel SP1 may be smaller than a thickness H2_RL1 of the first reflective electrode RL1 in the second sub-pixel SP2, and the thickness H2_RL1 of the first reflective electrode RL1 in the second sub-pixel SP2 may be smaller than a thickness H3_RL1 of the first reflective electrode RL1 in the third sub-pixel SP3.

In one or more embodiments, a thickness H1_RL2 of the second reflective electrode RL2 in the first sub-pixel SP1 may be smaller than a thickness H2_RL2 of the second reflective electrode RL2 in the second sub-pixel SP2, and the thickness H2_RL2 of the second reflective electrode RL2 in the second sub-pixel SP2 may be smaller than a thickness H3_RL2 of the second reflective electrode RL2 in the third sub-pixel SP3.

In one or more embodiments, a thickness H1_RL3 of the third reflective electrode RL3 in the first sub-pixel SP1 may be smaller than a thickness H2_RL3 of the third reflective electrode RL3 in the second sub-pixel SP2, and the thickness H2_RL3 of the third reflective electrode RL3 in the second sub-pixel SP2 may be smaller than a thickness H3_RL3 of the third reflective electrode RL3 in the third sub-pixel SP3.

In one or more embodiments, a thickness H1_RL4 of the fourth reflective electrode RL4 in the first sub-pixel SP1 may be smaller than a thickness H2_RL4 of the fourth reflective electrode RL4 in the second sub-pixel SP2, and the thickness H2_RL4 of the fourth reflective electrode RL4 in the second sub-pixel SP2 may be smaller than a thickness H3_RL4 of the fourth reflective electrode RL4 in the third sub-pixel SP3.

In one or more embodiments, a thickness H1_AND of the first electrode AND in the first sub-pixel SP1 may be smaller than a thickness H2_AND of the first electrode AND in the second sub-pixel SP2, and the thickness H2_AND of the first electrode AND in the second sub-pixel SP2 may be smaller than a thickness H3_AND of the first electrode AND in the third sub-pixel SP3.

In one or more embodiments, a thickness H1_IL1 of the first light emitting stack IL1 in the first sub-pixel SP1 may be smaller than a thickness H2_IL1 of the first light emitting stack IL1 in the second sub-pixel SP2, and the thickness H2_IL1 of the first light emitting stack IL1 in the second sub-pixel SP2 may be smaller than a thickness H3_IL1 of the first light emitting stack IL1 in the third sub-pixel SP3.

In one or more embodiments, a thickness H1_IL2 of the second light emitting stack IL2 in the first sub-pixel SP1 may be smaller than a thickness H2_IL2 of the second light emitting stack IL2 in the second sub-pixel SP2, and the thickness H2_IL2 of the second light emitting stack IL2 in the second sub-pixel SP2 may be smaller than a thickness H3_IL2 of the second light emitting stack IL2 in the third sub-pixel SP3.

In one or more embodiments, a thickness H1_IL3 of the third light emitting stack IL3 in the first sub-pixel SP1 may be smaller than a thickness H2_IL3 of the third light emitting stack IL3 in the second sub-pixel SP2, and the thickness H2_IL3 of the third light emitting stack IL3 in the second sub-pixel SP2 may be smaller than a thickness H3_IL3 of the third light emitting stack IL3 in the third sub-pixel SP3.

While the above paragraphs refer to each of the first sub-pixel SP1, second sub-pixel SP2, and the third sub-pixel SP3 and their respective components in the singular, the same may apply to some or all of the first sub-pixels SP1, the second sub-pixels SP2 the third sub-pixels SP3, and their respective components throughout the display layer 230.

The pixel defining film PDL may be arranged on a partial area of the electrode assembly ASS of each of the light emitting elements. The pixel defining film PDL may cover an edge of the electrode assembly ASS of each of the light emitting elements. The pixel defining film PDL serves to partition the first light emitting areas EA1, the second light emitting areas EA2, and the third light emitting areas EA3.

Each of the first light emitting areas EA1 may be defined as an area in which the first electrode AND, the light emitting stack IL, and the second electrode CAT are sequentially stacked in the first sub-pixel SP1 to emit light. Each of the second light emitting areas EA2 may be defined as an area in which the first electrode AND, the light emitting stack IL, and the second electrode CAT are sequentially stacked in the second sub-pixel SP2 to emit light. Each of the third light emitting areas EA3 may be defined as an area in which the first electrode AND, the light emitting stack IL, and the second electrode CAT are sequentially stacked in the third sub-pixel SP3 to emit light.

The pixel defining film PDL may include first to third pixel defining films PDL1, PDL2, and PDL3. The first pixel defining film PDL1 may be arranged on the edge of the first electrode AND of each of the light emitting elements, the second pixel defining film PDL2 may be arranged on the first pixel defining film PDL1, and the third pixel defining film PDL3 may be arranged on the second pixel defining film PDL2. The first pixel defining film PDL1, the second pixel defining film PDL2, and the third pixel defining film PDL3 may be formed of a silicon oxide (SiOₓ, where 0<x≤2)-based inorganic film, but the present disclosure is not limited thereto. the thickness of the first pixel defining film PDL1, the thickness of the second pixel defining film PDL2, and the thickness of the third pixel defining film PDL3 may each be about (approximately) 500 Å.

When the first pixel defining film PDL1, the second pixel defining film PDL2, and the third pixel defining film PDL3 are formed as a single pixel defining film, a first inorganic encapsulation layer TFE1 may be disconnected due to high step coverage between upper surface of the first electrode AND and the top of the single pixel defining film. The step coverage refers to a ratio of the thickness of a thin film applied at an inclined portion relative to the thickness of the thin film applied to a flat portion. If the step coverage is low, the possibility of the thin film being disconnected at the inclined portion may increase.

In order to prevent or reduce the likelihood of the first inorganic encapsulation layer TFE1 being disconnected due to the step coverage, the first pixel defining film PDL1, the second pixel defining film PDL2, and the third pixel defining film PDL3 may have a cross-sectional structure with a step-shaped level difference. For example, a width of the first pixel defining film PDL1 may be greater than a width of the second pixel defining film PDL2 and a width of the third pixel defining film PDL3, and the width of the second pixel defining film PDL2 may be greater than the width of third pixel defining film PDL3. The width of the first pixel defining film PDL1 refers to a horizontal length of the first pixel defining film PDL1 defined by the first direction DR1 and/or the second direction DR2.

Each of the plurality of trenches TRC may penetrate through the first pixel defining film PDL1, the second pixel defining film PDL2, and the third pixel defining film PDL3. At least one trench TRC may be arranged between adjacent sub-pixels of the sub-pixels SP1, SP2, and SP3. It is illustrated in FIG. 11 that two trenches TRC are arranged between adjacent sub-pixels of the sub-pixels SP1, SP2, and SP3, but the present disclosure is not limited thereto.

The light emitting stack IL may include a plurality of light emitting stacks IL1, IL2, and IL3. It is illustrated in the drawing that the light emitting stack IL has a three-tandem structure including a first light emitting stack IL1, a second light emitting stack IL2, and a third light emitting stack IL3, but the present disclosure is not limited thereto. For example, the light emitting stack IL may have a two-tandem structure including two stacks.

In the three-tandem structure, the light emitting stack IL may have a tandem structure including a plurality of light emitting stacks IL1, IL2, and IL3 that emit different lights. For example, the light emitting stack IL may include a first light emitting stack IL1 emitting light of a first color, a second light emitting stack IL2 emitting light of a third color, and a third light emitting stack IL3 emitting light of a second color. The first light emitting stack IL1, the second light emitting stack IL2, and the third light emitting stack IL3 may be sequentially stacked.

The first light emitting stack IL1 may have a structure in which a first hole transporting layer, a first organic light emitting layer emitting light of a first color, and a first electron transporting layer are sequentially stacked. The second light emitting stack IL2 may have a structure in which a second hole transporting layer, a second organic light emitting layer emitting light of a third color, and a second electron transporting layer are sequentially stacked. The third light emitting stack IL3 may have a structure in which a third hole transporting layer, a third organic light emitting layer emitting light of a second color, and a third electron transporting layer are sequentially stacked.

A first charge generation layer for supplying charges to the second light emitting stack IL2 and supplying electrons to the first light emitting stack IL1 may be arranged between the first light emitting stack IL1 and the second light emitting stack IL2. The first charge generation layer may include an N-type (kind) charge generation layer that supplies electrons to the first light emitting stack IL1 and a P-type (kind) charge generation layer that supplies holes to the second light emitting stack IL2. The N-type (kind) charge generation layer may include a dopant of a metallic material.

A second charge generation layer for supplying charges to the third light emitting stack IL3 and supplying electrons to the second light emitting stack IL2 may be arranged between the second light emitting stack IL2 and the third light emitting stack IL3. The second charge generation layer may include an N-type (kind) charge generation layer that supplies electrons to the second light emitting stack IL2 and a P-type (kind) charge generation layer that supplies holes to the third light emitting stack IL3.

The first light emitting stack IL1 may be arranged on the first electrodes AND and the pixel defining film PDL, and may be arranged on a bottom surface of each of the trenches TRC. Due to the trenches TRC, the first light emitting stack IL1 may be disconnected between the sub-pixels SP1, SP2, and SP3. The second light emitting stack IL2 may be arranged on the first light emitting stack IL1. Due to the trenches TRC, the second light emitting stack IL2 may be disconnected between the sub-pixels SP1, SP2, and SP3. A cavity or an empty space may be arranged between the first light emitting stack IL1 and the second light emitting stack IL2. The third light emitting stack IL3 may be arranged on the second light emitting stack IL2. The third light emitting stack IL3 may not be disconnected by the trenches TRC and may be arranged to cover the second light emitting stack IL2 in each of the trenches TRC. For example, in the three-tandem structure, each of the plurality of trenches TRC may be a structure for disconnecting the first and second light emitting stacks IL1 and IL2, the first charge generation layer, and the second charge generation layer of the display element layer EML between the sub-pixels SP1, SP2, and SP3. In one or more embodiments, in the two-tandem structure, each of the plurality of trenches TRC may be a structure for disconnecting the charge generation layer arranged between a lower light emitting stack and an upper light emitting stack.

In order to disconnect the first to third light emitting stacks IL1, IL2, and IL3 of the display element layer EML between the sub-pixels SP1, SP2, and SP3, other structures may be present instead of the trenches TRC. For example, instead of the trenches TRC, a partition wall having a reverse tapered shape may be arranged on the pixel defining film PDL.

The number of light emitting stacks IL1, IL2, and IL3 emitting different light is not limited to that illustrated in the drawing. For example, the light emitting stack IL may include two intermediate layers (e.g., light emitting stacks). In such embodiments, one of the two intermediate layers may be substantially the same as the first light emitting stack IL1, and the other thereof may include a second hole transporting layer, a second organic light emitting layer, a third organic light emitting layer, and a second electron transporting layer. In this case, a charge generation layer for supplying electrons to one intermediate layer and supplying charges to the other intermediate layer may be arranged between the two intermediate layers.

In one or more embodiments, it is illustrated in FIG. 13 that the first to third light emitting stacks IL1, IL2, and IL3 are all arranged in the first light emitting areas EA1, the second light emitting areas EA2, and the third light emitting areas EA3, but the present disclosure is not limited thereto. For example, the first light emitting stacks IL1 may be arranged in the first light emitting areas EA1 and may not be arranged in the second light emitting areas EA2 or the third light emitting areas EA3. In one or more embodiments, the second light emitting stacks IL2 may be arranged in the second light emitting areas EA2 and may not be arranged in the first light emitting areas EA1 or the third light emitting areas EA3. In one or more embodiments, the third light emitting stacks IL3 may be arranged in the third light emitting areas EA3 and may not be arranged in the first light emitting areas EA1 or the second light emitting areas EA2. In such embodiments, first to third color filters CF1, CF2, and CF3 of the optical layer OPL may not be provided.

The second electrode CAT (e.g., common electrode) may be arranged on the third light emitting stack IL3. The second electrode CAT may be arranged on the third light emitting stack IL3 in each of the plurality of trenches TRC. The second electrode CAT may be formed of a transparent conductive material (TCO) such as ITO or IZO capable of transmitting light, or a semi-transmissive conductive material such as magnesium (Mg), silver (Ag), or an alloy of magnesium (Mg) and silver (Ag). When the second electrode CAT is formed of a semi-transmissive conductive material, light emission efficiency may be increased in each of the first to third sub-pixels SP1, SP2, and SP3 by micro cavities.

The encapsulation layer TFE may be arranged on the display element layer EML. The encapsulation layer TFE may include one or more inorganic encapsulation layers TFE1 and TFE3 to prevent or reduce the likelihood of oxygen or moisture permeating into the display element layer EML. In one or more embodiments, the encapsulation layer TFE may include at least one organic film to protect the display element layer EML from foreign substances such as dust. For example, the encapsulation layer TFE may include a first inorganic encapsulation layer TFE1, an organic encapsulation layer TFE2, and a second inorganic encapsulation layer TFE3.

The first inorganic encapsulation layer TFE1 may be arranged on the second electrode CAT, the organic encapsulation layer TFE2 may be arranged on the first inorganic encapsulation layer TFE1, and the second inorganic encapsulation layer TFE3 may be arranged on the organic encapsulation layer TFE2. The first inorganic encapsulation layer TFE1 and the second inorganic encapsulation layer TFE3 may be formed as a multi-film in which one or more inorganic films of a silicon nitride layer (SiₓN_{y}, where 0<x≤3 and 0<y≤4), a silicon oxynitride layer (SiOₓN_{y}, where 0<x≤2 and 0<y≤2), a silicon oxide layer (SiOₓ, where 0<x≤2), a titanium oxide layer (TiOₓ, where 0<x≤3), and/or an aluminum oxide layer (AlₓO_{y}, where 0<x≤2 and 0<y≤3) are alternately stacked. The organic encapsulation layer TFE2 may be a monomer. In one or more embodiments, the organic encapsulation layer TFE2 may be an organic film made of an acrylic resin, an epoxy resin, a phenolic resin, a polyamide resin, or a polyimide resin.

The adhesive layer ADL may be arranged on the encapsulation layer TFEL. The adhesive layer ADL may be a layer for adhering the encapsulation layer TFE and a layer arranged thereon. The adhesive layer ADL may be a double-sided adhesive member. In one or more embodiments, the adhesive layer ADL may be a transparent adhesive member such as a transparent adhesive or a transparent adhesive resin.

The optical layer OPL may include a color filter layer CFL, a plurality of lenses LNS, a filling layer FIL, and a cover layer DCL. The color filter layer CFL may include first to third color filters CF1, CF2, and CF3. The first to third color filters CF1, CF2, and CF3 may be arranged on the adhesive layer ADL.

The first color filter CF1 may overlap the first light emitting areas EA1. The first color filter CF1 may be to transmit light of a first color, that is, light in a red wavelength band. The red wavelength band may be about (approximately) 600 nm to about 750 nm. The first color filter CF1 may be to transmit light of a first color among light emitted from the first light emitting areas EA1.

The second color filter CF2 may overlap the second light emitting areas EA2. The second color filter CF2 may be to transmit light of a second color, that is, light in a green wavelength band. The green wavelength band may be about (approximately) 480 nm to about 560 nm. The second color filter CF2 may be to transmit light of a second color among light emitted from the second light emitting areas EA2.

The third color filter CF3 may overlap the third light emitting areas EA3. The third color filter CF3 may be to transmit light of a third color, that is, light in a blue wavelength band. The red wavelength band may be about (approximately) 370 nm to about 460 nm. The third color filter CF3 may be to transmit light of a third color among light emitted from the third light emitting areas EA3.

Each of the plurality of lenses LNS may be arranged on each of the first color filter CF1, the second color filter CF2, and the third color filter CF3. Each of the plurality of lenses LNS may be a structure for increasing a ratio of light directed to the front of the display device 10. Each of the plurality of lenses LNS may have a cross-sectional shape that is convex in an upward direction.

The filling layer FIL may be arranged on the plurality of lenses LNS. The filling layer FIL may have a set or predetermined refractive index so that light travels in the third direction DR3 at an interface between the plurality of lenses LNS and the filling layer FIL. In one or more embodiments, the filling layer FIL may be a planarization layer. The filling layer FIL may be an organic film made of an acryl resin, an epoxy resin, a phenolic resin, a polyamide resin, or a polyimide resin.

The cover layer DCL may be arranged on the filling layer FIL. The cover layer DCL may be a glass substrate or a polymer resin such as an organic resin. When the cover layer DCL is a glass substrate, the cover layer DCL may be attached onto the filling layer FIL. In such embodiments, the filling layer FIL may serve to adhere the cover layer DCL to the rest of the display layer 230. When the cover layer DCL is a glass substrate, the cover layer DCL may serve as an encapsulation substrate. When the cover layer DCL is a polymer resin such as an organic resin, the cover layer DCL may be directly applied on the filling layer FIL.

In one or more embodiments, the display unit 200 may further include a polarizing plate arranged on the cover layer DCL. The polarizing plate may be arranged on one surface of the cover layer DCL. The polarizing plate may be a structure for preventing or reducing deterioration in visibility due to reflection of external light. The polarizing plate may include a linear polarizing plate and a phase retardation film. For example, the phase retardation film may be a λ/4 (quarter-wave) plate, but the present disclosure is not limited thereto. However, if (e.g., when) deterioration in visibility due to reflection of external light is sufficiently improved by the first to third color filters CF1, CF2, and CF3, the polarizing plate may also not be provided.

Hereinafter, a method for manufacturing a display device according to one or more embodiments will be described.

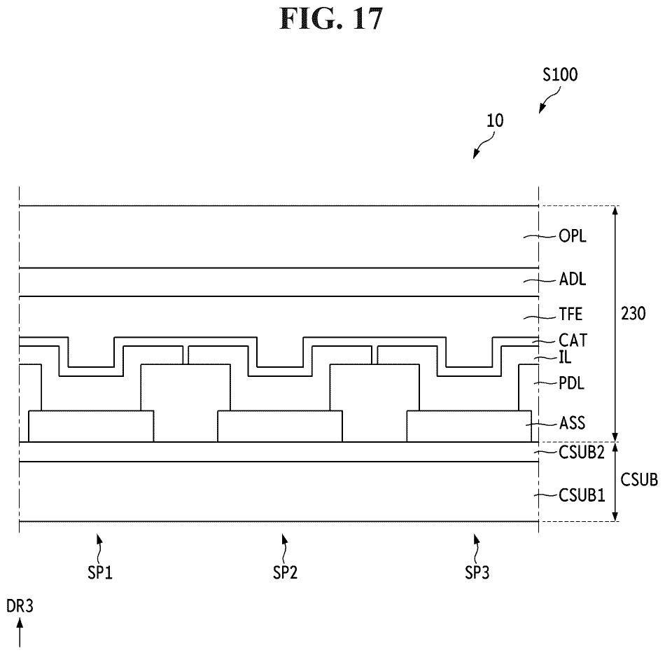

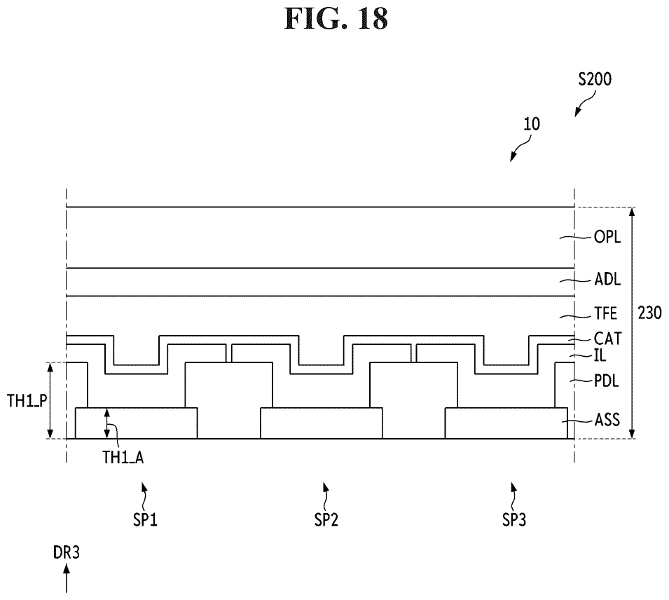

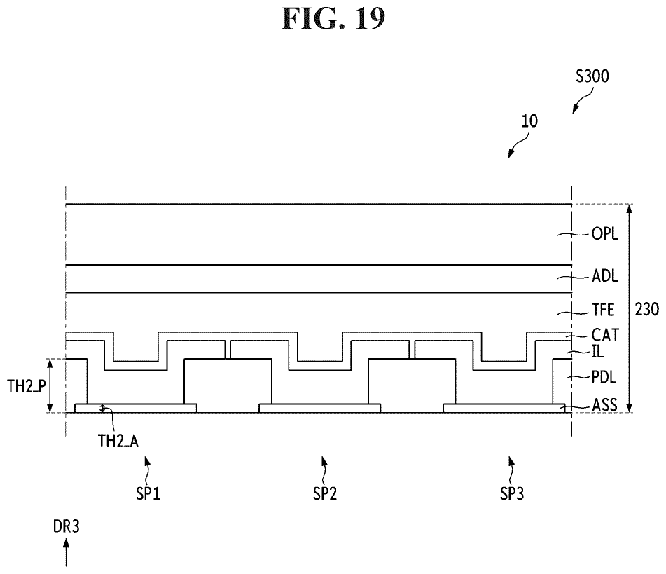

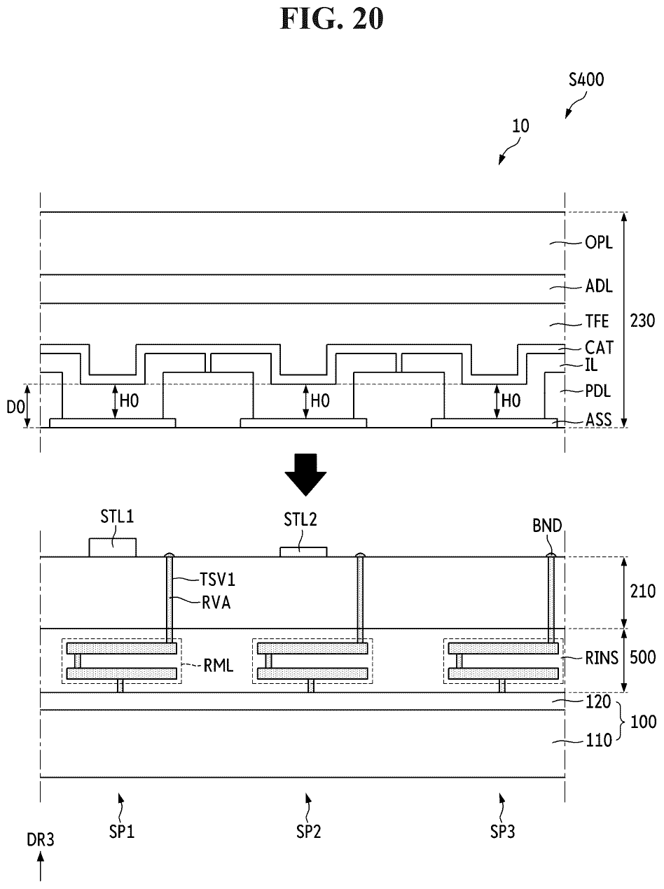

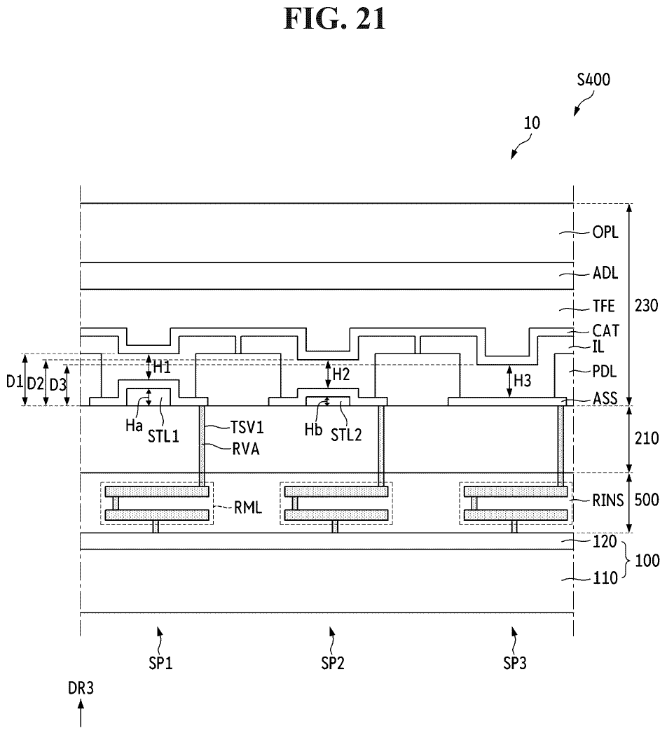

FIG. 16 is a flowchart illustrating a method for manufacturing a display device according to one or more embodiments of the present disclosure. FIG. 17 is a cross-sectional view illustrating step (e.g., act or task) S100 of FIG. 16, according to one or more embodiments of the present disclosure. FIG. 18 is a cross-sectional view illustrating step (e.g., act or task) S200 of FIG. 16, according to one or more embodiments of the present disclosure. FIG. 19 is a cross-sectional view illustrating step (e.g., act or task) S300 of FIG. 16, according to one or more embodiments of the present disclosure. FIGS. 20 and 21 are cross-sectional views illustrating step (e.g., act or task) S400 of FIG. 16, according to one or more embodiments of the present disclosure.

Referring to FIGS. 16 to 21, a method S1 for manufacturing a display device according to one or more embodiments may include a step (e.g., act or task) (S100) of forming a display layer on a carrier substrate, a step (e.g., act or task) (S200) of detaching the display layer by removing the carrier substrate, a step (e.g., act or task) (S300) of polishing a lower surface of the display layer, and a step (e.g., act or task) (S400) of coupling the display layer and a second single crystal semiconductor substrate.

First, as illustrated in FIG. 17, in the step (e.g., act or task) (S100) of forming the display layer on the carrier substrate, a carrier substrate CSUB may be provided. The carrier substrate CSUB may include a first carrier substrate CSUB1 and a second carrier substrate CSUB2.

The first carrier substrate CSUB1 may be made of a hard material. For example, the first carrier substrate CSUB1 may be made of glass.

The second carrier substrate CSUB2 may be made of a soft material. The second carrier substrate CSUB2 may be made of a polymer resin having a thickness smaller than that of the first carrier substrate CSUB1. For example, the second carrier substrate CSUB2 may be formed of an organic material such as an acryl resin, an epoxy resin, a phenolic resin, a polyamide resin, or a polyimide resin. The second carrier substrate CSUB2 may be referred to as a plastic substrate because of being made of the polymer resin. In one or more embodiments, the second carrier substrate CSUB2 may have a multilayer structure.

Thereafter, the display layer 230 may be formed on the carrier substrate CSUB. Because the display layer 230 has been described above, a detailed description thereof will not be provided.

Next, as illustrated in FIG. 18, in the step (e.g., act or task) (S200) of detaching the display layer by removing the carrier substrate, the carrier substrate CSUB may be removed from the display layer 230.

In one or more embodiments, the carrier substrate CSUB may be detached by a laser peeling process. For example, the carrier substrate CSUB may be detached by an excimer laser peeling (ELP) process or a solid state laser peeling (SLP) process.

Next, as illustrated in FIG. 19, in the step (e.g., act or task) (S300) of polishing the lower surface of the display layer, lower surfaces of the electrode assemblies ASS and the pixel defining film PDL arranged on the lower surface of the display layer 230 may be polished. For example, the first reflective electrodes RL1 (see, e.g., FIG. 13) and the pixel defining film PDL arranged at the lowest portion of the electrode assemblies ASS may be polished.

In one or more embodiments, the electrode assemblies ASS and pixel defining film PDL may be polished by a chemical mechanical polishing (CMP) process.

In the method S1 for manufacturing the display device according to one or more embodiments, a thickness TH2_A of the electrode assemblies ASS and a thickness TH2_P of the pixel defining film PDL after the step (e.g., act or task) (S300) of polishing the lower surface of the display layer may be smaller than a thickness TH1_A of the electrode assemblies ASS and a thickness TH1_P of the pixel defining film PDL before the step (e.g., act or task) (S300) of polishing the lower surface of the display layer.

Because the method S1 for manufacturing the display device according to one or more embodiments includes the step (e.g., act or task) (S300) of polishing the lower surface of the display layer, a surface shape of the reflective electrode layers RL of the electrode assemblies ASS may be substantially uniform in the step (e.g., act or task) (S200) of detaching the display layer by removing the carrier substrate. Accordingly, color mixing and deterioration of white angular difference (WAD) of each of the sub-pixels SP1, SP2, and SP3 may be prevented or reduced. WAD is an item that evaluates a change in white light characteristics according to an observation angle of the display device 10, and is an index that may confirm the degree of improvement in the light viewing angle.

Next, as illustrated in FIGS. 20 and 21, in the step (e.g., act or task) (S400) of coupling the display layer and the second single crystal semiconductor substrate, a first step layer STL1 and a second step layer STL2 may be arranged on the second single crystal semiconductor substrate 210. Thereafter, the second single crystal semiconductor substrate 210 and the display layer 230 may be coupled with the first step layer STL1 and the second step layer STL2 interposed therebetween.

It is illustrated in the drawings that the second single crystal semiconductor substrate 210 is coupled to the display layer 230 while being coupled to the driver 100 and the connection wiring layer 500, but the present disclosure is not limited thereto. For example, the second single crystal semiconductor substrate 210 may first be coupled to the display layer 230 and then the second single crystal semiconductor substrate 210 may be coupled to the driver 100 and the connection wiring layer 500.

Before the step (e.g., act or task) (S400) of coupling the display layer and the second single crystal semiconductor substrate, a distance HO between the second electrode CAT and the electrode assemblies ASS in the first to third sub-pixels SP1, SP2, and SP3 may be equal to each other. In one or more embodiments, before the step (e.g., act or task) (S400) of coupling the display layer and the second single crystal semiconductor substrate, a distance DO between the lower surface of the display element layer EML and the lower surface of the second electrode CAT in the first to third sub-pixels SP1, SP2, and SP3 may be equal to each other.

After the step (e.g., act or task) (S400) of coupling the display layer and the second single crystal semiconductor substrate, the electrode assemblies ASS and the light emitting stacks IL in the first sub-pixels SP1 and the second sub-pixels SP2 may be compressed by the first step layer STL1 and the second step layer STL2, respectively. Accordingly, the shapes of the electrode assembly ASS and the light emitting stack IL may change.

For example, as described above, after the step (e.g., act or task) (S400) of coupling the display layer and the second single crystal semiconductor substrate, for each of the pixels PX, the distance H1 between the second electrode CAT and the electrode assembly ASS in the first sub-pixel SP1 may be smaller than the distance H2 between the second electrode CAT and the electrode assembly ASS in the second sub-pixel SP2 and the distance H3 between the second electrode CAT and the electrode assembly ASS in the third sub-pixel SP3, and the distance H2 between the second electrode CAT and the electrode assembly ASS in the second sub-pixel SP2 may be smaller than the distance H3 between the second electrode CAT and the electrode assembly ASS in the third sub-pixel SP3. In one or more embodiments, for each of the pixels PX, the distance D1 between the lower surface of the display element layer EML and the lower surface of the second electrode CAT in the first sub-pixel SP1 may be greater than the distance D2 between the lower surface of the display element layer EML and the lower surface of the second electrode CAT in the second sub-pixel SP2 and the distance D3 between the lower surface of the display element layer EML and the lower surface of the second electrode CAT in the third sub-pixel SP3, and the distance D2 between the lower surface of the display element layer EML and the lower surface of the second electrode CAT in the second sub-pixel SP2 may be greater than the distance D3 between the lower surface of the display element layer EML and the lower surface of the second electrode CAT in the third sub-pixel SP3.

Accordingly, the light emission efficiency of the display device 10 may be improved by adjusting the resonance distance of the light emitted from the light emitting elements in the first to third sub-pixels SP1, SP2, and SP3 of the pixels PX.

In one or more embodiments, a binder BND may be arranged on the first through hole TSV1. The binder BND may serve to electrically connect the electrode assemblies ASS and the conductive vias RVA and to physically couple the display layer 230 and the second single crystal semiconductor substrate 210. For example, the binder BND may include a conductive paste.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Further, the use of “may” when describing embodiments of the present disclosure refers to “one or more embodiments of the present disclosure.”

As used herein, the term “substantially,” “about,” and similar terms are used as terms of approximation and not as terms of degree, and are intended to account for the inherent deviations in measured or calculated values that would be recognized by those of ordinary skill in the art. “Substantially” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” may mean within one or more standard deviations, or within ±30%, 20%, 10%, 5% of the stated value.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The display device, electronic apparatus, device for manufacturing the display device, or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

A person of ordinary skill in the art, in view of the present disclosure in its entirety, would appreciate that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. It is to be understood that the foregoing is an illustration of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a first single crystal semiconductor substrate on which a first transistor is located;
a connection wiring layer on the first single crystal semiconductor substrate and comprising a connection wiring connected to the first transistor;
a second single crystal semiconductor substrate on the connection wiring layer and comprising a via connected to the connection wiring;
a display element layer on the second single crystal semiconductor substrate and comprising a first light emitting element in a first pixel of the display device and a second light emitting element in a second pixel of the display device; and
a first step layer below the display element layer in the first pixel,
wherein the first light emitting element and the second light emitting element each comprise:
an electrode assembly comprising a reflective electrode layer connected to the via and a first electrode on the reflective electrode layer;
a light emitting stack on the electrode assembly; and
a second electrode on the light emitting stack, and
wherein a distance between the electrode assembly and the second electrode in the first pixel is different from a distance between the electrode assembly and the second electrode in the second pixel.

2. The display device of claim 1, wherein the distance between the electrode assembly and the second electrode in the first pixel is less than the distance between the electrode assembly and the second electrode in the second pixel.

3. The display device of claim 1, wherein a first portion of the electrode assembly of the first light emitting element is in direct contact with the first step layer.

4. The display device of claim 3, wherein
a second portion of the electrode assembly of the first light emitting element is not in contact with the first step layer, and
the second portion is in direct contact with the second single crystal semiconductor substrate.

5. The display device of claim 4, further comprising a pixel defining film between the first light emitting element and the second light emitting element,
wherein the second portion overlaps the pixel defining film.

6. The display device of claim 4, wherein the second portion is connected to the via.

7. The display device of claim 1, wherein the first step layer is covered by the electrode assembly of the first light emitting element.

8. The display device of claim 7, wherein a shape of the electrode assembly of the first light emitting element conforms to shapes of upper and side surfaces of the first step layer.

9. The display device of claim 7, wherein the electrode assembly of the second light emitting element has a flat shape.

10. The display device of claim 7, wherein an entirety of a lower surface of the electrode assembly of the second light emitting element is in contact with the second single crystal semiconductor substrate.

11. The display device of claim 1, wherein
the display element layer further comprises a third light emitting element in a third pixel of the display device,
the display device further comprises a second step layer below the display element layer in the third pixel, and
a thickness of the second step layer is different from a thickness of the first step layer.

12. The display device of claim 11, wherein the distance between the electrode assembly and the second electrode in the first pixel, the distance between the electrode assembly and the second electrode in the second pixel, and a distance between the electrode assembly and the second electrode in the third pixel are different from each other.

13. The display device of claim 12, wherein
a thickness of the electrode assembly in the first pixel is smaller than a thickness of the electrode assembly in the third pixel, and
the thickness of the electrode assembly in the third pixel is smaller than a thickness of the electrode assembly in the second pixel.

14. The display device of claim 12, wherein
a thickness of the light emitting stack in the first pixel is smaller than a thickness of the light emitting stack in the third pixel, and
the thickness of the light emitting stack in the third pixel is smaller than a thickness of the light emitting stack in the second pixel.

15. The display device of claim 1, wherein a distance between a lower surface of the display element layer and a lower surface of the second electrode in the first pixel is greater than a distance between a lower surface of the display element layer and a lower surface of the second electrode in the second pixel.

16. A display device comprising:
a first single crystal semiconductor substrate on which a first transistor is located;
a second single crystal semiconductor substrate on the first single crystal semiconductor substrate and comprising a via connected to the first transistor;
an electrode assembly comprising a reflective electrode layer connected to the via and a first electrode on the reflective electrode layer, the electrode assembly comprising a first electrode assembly and a second electrode assembly spaced from each other;
a first step layer below the first electrode assembly;
a light emitting stack on the first electrode; and
a second electrode on the light emitting stack,
wherein a distance between the first electrode assembly and the second electrode is different from a distance between the second electrode assembly and the second electrode.

17. The display device of claim 16, wherein the distance between the first electrode assembly and the second electrode is less than the distance between the second electrode assembly and the second electrode.

18. The display device of claim 16, wherein
the electrode assembly comprises a third electrode assembly spaced from the first electrode assembly and the second electrode assembly,
the display device further comprises a second step layer below the third electrode assembly, and
a thickness of the second step layer is different from a thickness of the first step layer.

19. The display device of claim 18, wherein the distance between the first electrode assembly and the second electrode, the distance between the second electrode assembly and the second electrode, and a distance between the third electrode assembly and the second electrode are different from each other.

20. The display device of claim 16, wherein a distance between an upper surface of the second single crystal semiconductor substrate and a lower surface of the second electrode in an area where the first electrode assembly is located is greater than a distance between the upper surface of the second single crystal semiconductor substrate and the lower surface of the second electrode in an area where the second electrode assembly is located.

21. An electronic device comprising the display device of claim 1.

22. The electronic device of claim 21, wherein the electronic device is a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, or a head-mounted display (HMD).

23. An electronic device comprising the display device of claim 16.
